(19) United States
(12) Patent Application Publication
(10) Pub. No.: US 2025/0234563 A1
(43) Pub. Date: Jul. 17, 2025

(54) NONVOLITILE MEMORY DEVICE AND MEMORY PACKAGE INCLUDING THE SAME

(71) Applicant: SAMSUNG ELECTRONICS CO., LTD., Suwon-si (KR)

(72) Inventors: Guyeol Kim, Suwon-si (KR); Ahreum Kim, Suwon-si (KR); Ansoo Park, Suwon-si (KR); Changyeon Yu, Suwon-si (KR)

(73) Assignee: SAMSUNG ELECTRONICS CO., LTD., Suwon-si (KR)

(21) Appl. No.: 18/954,080

(22) Filed: Nov. 20, 2024

(30) Foreign Application Priority Data
Jan. 17, 2024 (KR) 10-2024-0007476

(51) Int. Cl. H10B 80/00; H01L 23/00; H01L 25/065; H01L 25/18

(52) U.S. Cl. CPC H10B 80/00; H01L 24/08; H01L 25/0657; H01L 25/18; H01L 2224/08145; H01L 2924/1431; H01L 2924/14511

(57) ABSTRACT

A nonvolatile memory device includes a first semiconductor layer including a first substrate, a memory cell array on the first substrate and in a cell array area, and a plurality of word lines and a string selection line extending in a first direction parallel to an upper surface of the first substrate and provided along a second direction intersecting the first direction, the plurality of word lines and the string selection line being connected to the memory cell array, and a second semiconductor layer including a second substrate, and a peripheral circuit on the second substrate and configured to control the memory cell array, the peripheral circuit including a plurality of word line pass transistors, each word line pass transistor of the plurality of word line pass transistors connected to one word line of the plurality of word lines.

### CROSS-REFERENCE TO RELATED APPLICATION

This application is based on and claims priority under 35 USC § 119 to Korean Patent Application No. 10-2024-0007476, filed on Jan. 17, 2024, in the Korean Intellectual Property Office, the disclosure of which is incorporated by reference herein in its entirety.

### BACKGROUND

Example embodiments of the disclosure relate to a nonvolatile memory device and a memory package including the nonvolatile memory device.

Recently, to achieve a high degree of integration of memory devices, memory devices having a vertical structure in which memory cells are stacked perpendicularly from a surface of a substrate have been developed. Even if the vertical structure is adopted to reduce the size of the memory devices, reduction in the size of the memory devices may be limited because a peripheral circuit for driving a memory cell array and wiring structures for electrical connection therewith become complex.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a nonvolatile memory device having a reduced chip size and having an improved operating performance.

One or more example embodiments provide a memory package including the nonvolatile memory device.

Additional aspects will be set forth in part in the description which follows and, in part, will be apparent from the description, or may be learned by practice of the presented embodiments.

According to an aspect of an example embodiment, a nonvolatile memory device may include a first semiconductor layer including a first substrate, a memory cell array on the first substrate and in a cell array area, and a plurality of word lines and a string selection line extending in a first direction parallel to an upper surface of the first substrate and provided along a second direction intersecting the first direction, the plurality of word lines and the string selection line being connected to the memory cell array, and a second semiconductor layer including a second substrate, and a peripheral circuit on the second substrate and configured to control the memory cell array, the peripheral circuit including a plurality of word line pass transistors, each word line pass transistor of the plurality of word line pass transistors connected to one word line of the plurality of word lines, a plurality of string selection line pass transistors connected to the string selection line, and a plurality of string selection line ground transistors in the cell array area and spaced apart from the plurality of string selection line pass transistors, the plurality of string selection line ground transistors configured to provide a ground voltage to the string selection line.

According to an aspect of an example embodiment, a memory package may include a base substrate, and a plurality of memory chips on the base substrate, where each memory chip of the plurality of memory chips includes a first semiconductor layer including a first substrate, a memory cell array on the first substrate and in a cell array area, and a plurality of word lines and a string selection line extending in a first direction parallel to an upper surface of the first substrate and provided along a second direction intersecting the first direction, the plurality of word lines and the string selection line being connected to the memory cell array, and a second semiconductor layer including a second substrate and a peripheral circuit on the second substrate and configured to control the memory cell array, the peripheral circuit including a plurality of word line pass transistors, each word line pass transistor of the plurality of word line pass transistors connected to one word line of the plurality of word lines, a plurality of string selection line pass transistors connected to the string selection line, and a plurality of string selection line ground transistors in the cell array area and spaced apart from the plurality of string selection line pass transistors, the plurality of string selection line ground transistors configured to provide a ground voltage to the string selection line.

According to an aspect of an example embodiment, a nonvolatile memory device may include a first semiconductor layer including a first substrate, a memory cell array on the first substrate and in a cell array area, the memory cell array including a first memory cell array and a second memory cell array adjacent to the first memory cell array, and a plurality of word lines and a string selection line extending in a first direction parallel to an upper surface of the first substrate and provided along a second direction intersecting the first direction, the plurality of word lines and the string selection line being connected to the memory cell array, and a second semiconductor layer including a second substrate, a peripheral circuit on the second substrate and configured to control the memory cell array, and a first well, a second well, and a third well, where the peripheral circuit includes a plurality of word line pass transistors in the first well, each word line pass transistor of the plurality of word line pass transistors connected to one word line of the plurality of word lines, a plurality of string selection line pass transistors in the second well and connected to the string selection line, and a plurality of string selection line ground transistors in the third well, in the cell array area, and spaced apart from the plurality of string selection line pass transistors, the plurality of string selection line ground transistors configured to provide a ground voltage to the string selection line, where the first memory cell array and the second memory cell array share the plurality of word lines and the string selection line, the third well is in the cell array area, and the first well and the second well are in a decoder area adjacent to the cell array area in the first direction.

### BRIEF DESCRIPTION OF DRAWINGS

The above and other aspects, features, and advantages of certain example embodiments of the present disclosure will be more apparent from the following description taken in conjunction with the accompanying drawings, in which;

FIG. 1 is a cross-sectional view of a nonvolatile memory device according to one or more embodiments;

FIG. 2 is a plan view of a second semiconductor layer included in a nonvolatile memory device according to one or more embodiments;

FIG. 3 is a cross-sectional view of an example of a second substrate included in a second semiconductor layer in FIG. 2 according to one or more embodiments;

FIG. 4 is a cross-sectional view of an example of a nonvolatile memory device according to one or more embodiments;

FIGS. 5, 6, 7, and 8 are plan views of examples of a second semiconductor layer included in a nonvolatile memory device according to one or more embodiments;

FIGS. 9 and 10 are cross-sectional views of examples of a nonvolatile memory device according to one or more embodiments;

FIG. 11 is a block diagram illustrating a nonvolatile memory device according to one or more embodiments;

FIG. 12 is a perspective view of an example of a memory block included in a memory cell array of a nonvolatile memory device according to one or more embodiments;

FIG. 13 is a circuit diagram illustrating an equivalent circuit of a memory block according to one or more embodiments;

FIG. 14 is a block diagram illustrating an example of an address decoder included in a nonvolatile memory device according to one or more embodiments;

FIGS. 15 and 16 are cross-sectional views of a memory package including a nonvolatile memory device according to one or more embodiments;

FIG. 17 is a block diagram illustrating an electronic system including a nonvolatile memory device according to one or more embodiments;

FIG. 18 is a perspective view of an electronic system including a nonvolatile memory device according to one or more embodiments; and

FIG. 19 is a cross-sectional view of a nonvolatile memory device according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof may be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

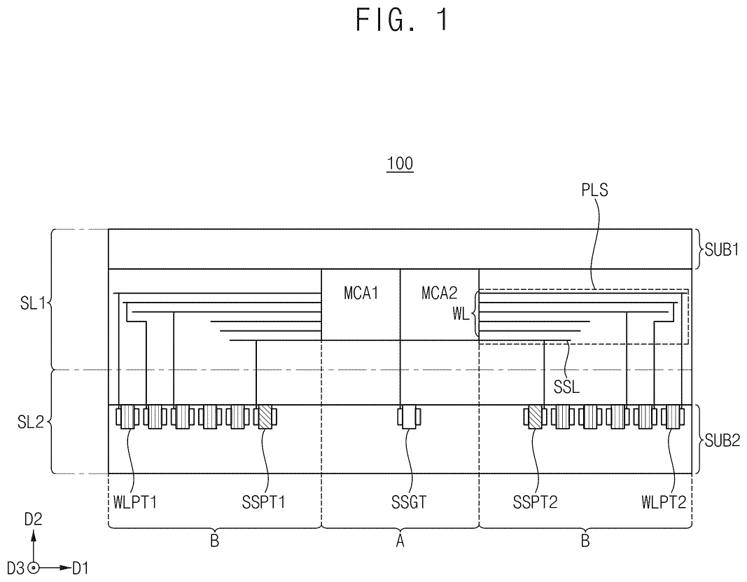

FIG. 1 is a cross-sectional view of a nonvolatile memory device according to one or more embodiments.

In FIG. 1, two directions that are each parallel or substantially parallel to a first surface (e.g., a top surface) of a substrate and crossing each other may be referred to as a first direction D1 (e.g., a X-axis direction) and a third direction D3 (e.g., a Y-axis direction). In addition, a direction vertical or substantially vertical to the first surface of the substrate may be referred to as a second direction D2 (e.g., a Z-axis direction). For example, the first and third directions D1 and D3 may be perpendicular or substantially perpendicular to each other. In addition, the second direction D2 may be perpendicular or substantially perpendicular to both the first and third directions D1 and D3. Further, a direction indicated by an arrow in the figures and a reverse direction thereof may be considered as the same direction. The definition of the first, second and third directions D1, D2 and D3 are same in the subsequent figures.

Referring to FIG. 1, a nonvolatile memory device 100 may include a first semiconductor layer SL1 and a second semiconductor layer SL2.

The first semiconductor layer SL1 and the second semiconductor layer SL2 may be disposed or stacked in the second direction D2. For example, the second semiconductor layer SL2 may be disposed below the first semiconductor layer SL1 in the second direction D2, and the first semiconductor layer SL1 may be stacked on the second semiconductor layer SL2 in the second direction D2. However, embodiments are not limited thereto, and as the nonvolatile memory device 100 is turned over during the manufacturing process, the second semiconductor layer SL2 may be stacked on the first semiconductor layer SL1 in the second direction D2.

The first semiconductor layer SL1 may include a first substrate SUB1, a plurality of word lines WL, a string selection line SSL, and memory cell arrays MCA1 and MCA2. The first semiconductor layer SL1 may be referred to as a memory cell region.

For example, the plurality of word lines WL, the string selection line SSL, and the memory cell arrays MCA1 and MCA2 may be disposed/formed on the first substrate SUB1. For example, each of the plurality of word lines WL and the string selection line SSL may extend in the first direction D1, the plurality of word lines WL and the string selection line SSL may be disposed along the third direction D3, and the plurality of word lines WL and the string selection line SSL may be stacked in the second direction D2. For example, the memory cell arrays MCA1 and MCA2 may be connected to the plurality of word lines WL and the string selection line SSL.

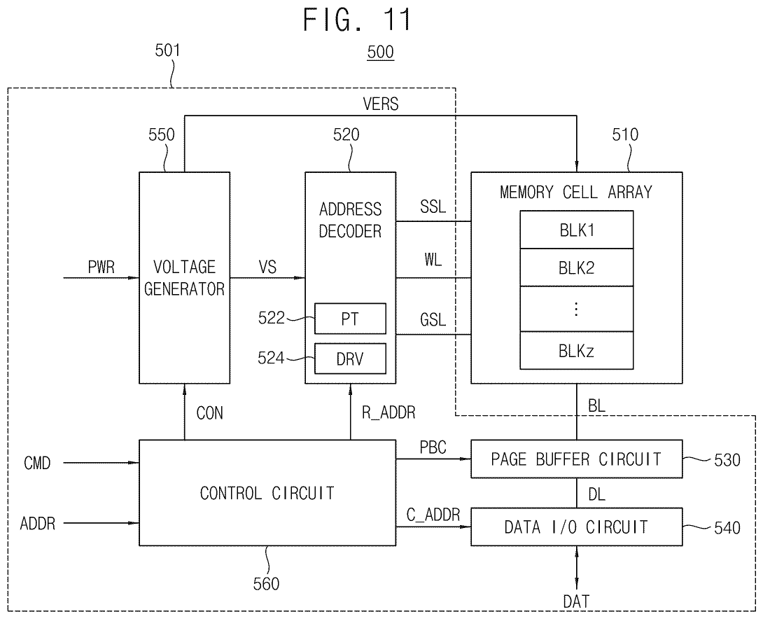

The second semiconductor layer SL2 may include a second substrate SUB2, and a peripheral circuit that controls the memory cell arrays MCA1 and MCA2. The peripheral circuit may include a plurality of word line pass transistors WLPT1 and WLPT2, a plurality of string selection line pass transistors SSPT1 and SSPT2, and a plurality of string selection line ground transistors SSGT. For example, the second semiconductor layer SL2 may be referred to as a peripheral circuit region. The peripheral circuit will be described with reference to FIG. 11.

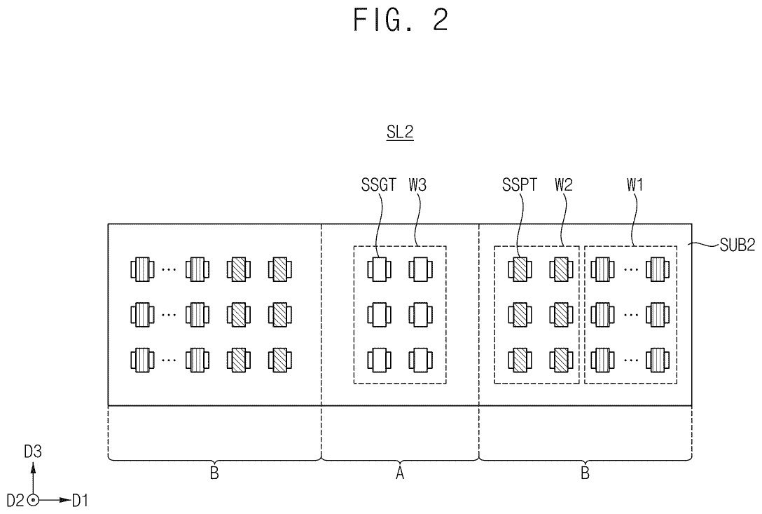

For example, the peripheral circuit may be disposed/formed on the second substrate SUB2. For example, the plurality of word line pass transistors WLPT1 and WLPT2, the plurality of string selection line pass transistors SSPT1 and SSPT2, and the plurality of string selection line ground transistors SSGT may be disposed on the second substrate SUB2. As will be described with reference to FIG. 2, wells in which transistors are formed may be formed in the second substrate SUB2.

The plurality of word line pass transistors WLPT1 and WLPT2 may be connected to the plurality of word lines WL. The plurality of string selection line pass transistors SSPT1 and SSPT2, and the plurality of string selection line ground transistors SSGT may be connected to the string selection line SSL. In addition, the plurality of word line pass transistors WLPT1 and WLPT2, the plurality of string selection line pass transistors SSPT1 and SSPT2, and the plurality of string selection line ground transistors SSGT may control the electrical connection between the memory cell arrays MCA1 and MCA2 and the peripheral circuit.

For example, patterns for electrically connecting the memory cell arrays MCA1 and MCA2 (e.g., the plurality of word lines WL and the string selection line SSL) and circuits formed in the second semiconductor layer SL2 (e.g., the plurality of word line pass transistors WLPT1 and WLPT2, the plurality of string selection line pass transistors SSPT1 and SSPT2, and the plurality of string selection line ground transistors SSGT) may be formed in the first semiconductor layer SL1 and/or the second semiconductor layer SL2.

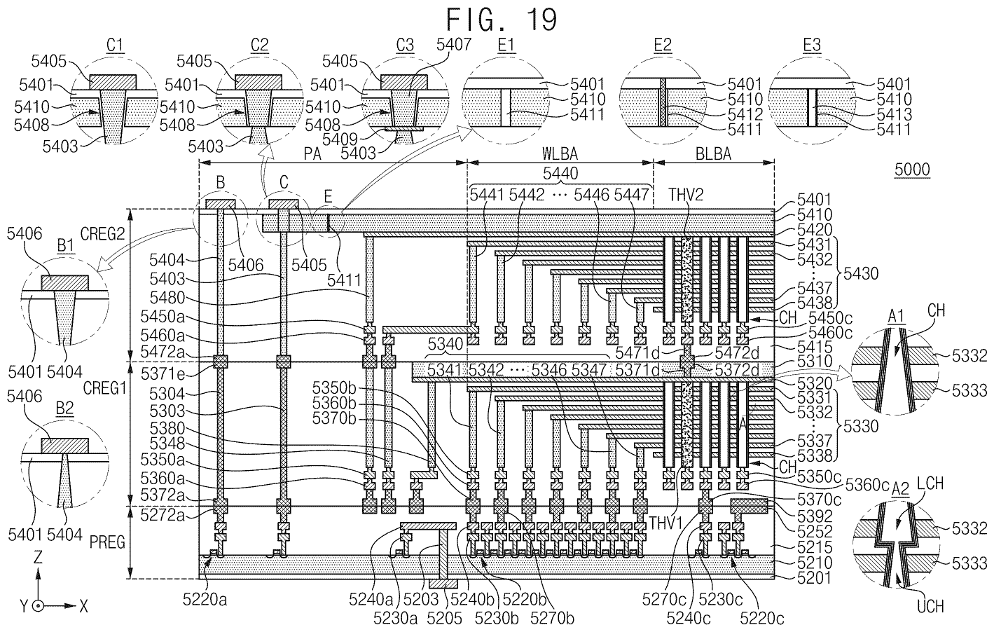

The size of the nonvolatile memory device 100 may be reduced by adopting a structure in which the peripheral circuit and the memory cell arrays MCA1 and MCA2 are stacked on each other (e.g., a bonding vertical NAND (BVNAND) structure in which the peripheral circuit and the memory cell arrays MCA1 and MCA2 are disposed in the second direction D2). For example, the first semiconductor layer SL1 may include first metal pads, and the second semiconductor layer SL2 may include second metal pads. For example, after manufacturing the first semiconductor layer SL1 and the second semiconductor layer SL2 on separate wafers, the first and second metal pads may be connected by a bonding method such that the first and second semiconductor layers SL1 and SL2 are electrically connected. The BVNAND structure will be described with reference to FIG. 19.

However, embodiments are not limited thereto, and a cell over periphery (COP) structure may be adopted in which the peripheral circuit is formed at the bottom and then memory cell arrays MCA1 and MCA2 are stacked on the peripheral circuit within one process.

For example, the first substrate SUB1 may be a support layer that supports the components of the first semiconductor layer SL1, and the second substrate SUB2 may be a support layer that supports the components of the second semiconductor layer SL2. For example, each of the first and second substrates SUB1 and SUB2 may be a silicon substrate and may also be referred to as a base substrate.

For example, the memory cell arrays MCA1 and MCA2 may include a first memory cell array MCA1 and a second memory cell array MCA2. For example, the first memory cell array MCA1 and the second memory cell array MCA2 may share the plurality of word lines WL and the string selection line SSL. Although not shown in detail, the plurality of word lines WL and the string selection line SSL may be extended to penetrate the first memory cell array MCA1 and the second memory cell array MCA2 along the first direction D1.

For example, in a cross-sectional view, the plurality of word lines WL and the string selection line SSL may be formed in a step-shaped multi-layer structure PLS. For example, the memory cell arrays MCA1 and MCA2 may be disposed in a cell array area A, and the step-shaped multi-layer structure PLS may be disposed in an X decoder area B adjacent to the cell array area A in the first direction D1. For example, the X decoder area B may be referred to as a word line extension area.

For example, the plurality of word line pass transistors WLPT1 and WLPT2 may include first word line pass transistors WLPT1 and second word line pass transistors WLPT2. For example, the plurality of string selection line pass transistors SSPT1 and SSPT2 may include first string selection line pass transistors SSPT1 and second string selection line pass transistors SSPT2. For example, the first word line pass transistors WLPT1 and the first string selection line pass transistors SSPT1 may be disposed in the X decoder area B adjacent to the left side of the cell array area A. For example, the second word line pass transistors WLPT2 and the second string selection line pass transistors SSPT2 may be disposed in the X decoder area B adjacent to the right side of the cell array area A.

For example, the cell array area A may be referred to as a buried area, and the X decoder area B may be referred to as a non-buried area. For example, the plurality of string selection line ground transistors SSGT may be disposed in the cell array area A, and thus the chip size may be reduced as the non-buried area is reduced. For example, the plurality of string selection line ground transistors SSGT may be disposed adjacent to a boundary between the first memory cell array MCA1 and the second memory cell array MCA2. The plurality of string selection line ground transistors SSGT may be disposed adjacent to the center of the string selection line SSL in the first direction D1, and data loading speed may increase. Accordingly, the driving performance of the nonvolatile memory device may be improved.

FIG. 2 is a plan view of a second semiconductor layer included in a nonvolatile memory device according to one or more embodiments.

Referring to FIG. 2, a second semiconductor layer SL2 may include a first well W1, a second well W2, and a third well W3 formed in a second substrate SUB2. For example, a well may represent an area where transistors are formed during the manufacturing process of a semiconductor device. For example, a plurality of word line pass transistors WLPT may be formed in the first well W1, a plurality of string selection line pass transistors SSPT may be formed in the second well W2, and a plurality of string selection line ground transistors SSGT may be formed in the third well W3.

For example, the second well W2 and the third well W3 may be spaced apart from each other in the first direction D1. For example, the second well W2 and the first well W1 may be adjacent to each other in the first direction D1. For example, the third well W3 may be formed in a cell array area A, and the first and second wells W1 and W2 may be formed in an X decoder area B.

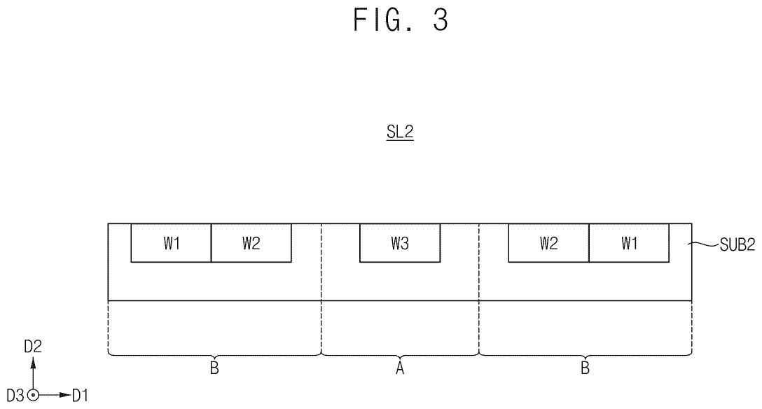

FIG. 3 is a cross-sectional view of an example of a second substrate included in a second semiconductor layer in FIG. 2 according to one or more embodiments. Hereinafter, description of aspects similar to those of FIG. 2 may be omitted.

Referring to FIG. 3, the first to third wells W1, W2, and W3 may be formed in the second substrate SUB2 included in the second semiconductor layer SL2. For example, the first to third wells W1, W2, and W3 may be formed by performing a diffusion process or an ion implantation process on the second substrate SUB2 which is a semiconductor substrate. FIG. 3 illustrates an example where the second well W2 and the first well W1 are adjacent to each other in the first direction D1, and the second well W2 and the third well W3 are spaced apart from each other in the first direction D1. Likewise, the third well W3 may be formed in the cell array area A, and the first and second wells W1 and W2 may be formed in the X decoder area B.

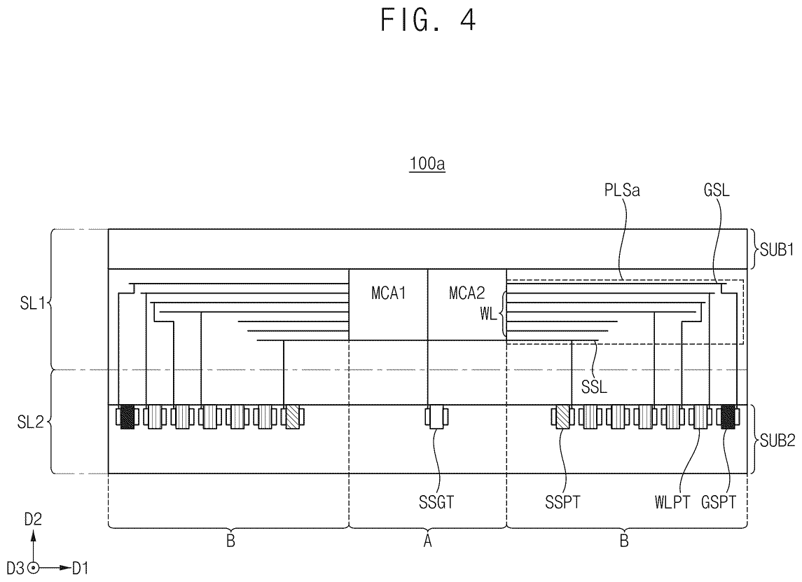

FIG. 4 is a cross-sectional view of an example of a nonvolatile memory device according to one or more embodiments.

Referring to FIG. 4, a nonvolatile memory device 100a may include a first semiconductor layer SL1a and a second semiconductor layer SL2a.

Compared to the first semiconductor layer SL1 in FIG. 1, the first semiconductor layer SL1a may further include a ground selection line GSL. Compared to the second semiconductor layer SL2 in FIG. 1, the second semiconductor layer SL2a may further include a plurality of ground selection line pass transistors GSPT. Hereinafter, description of aspects similar to those of FIG. 2 may be omitted.

For example, a first memory cell array MCA1a and a second memory cell array MCA2a may share a plurality of word lines WL, a string selection line SSL, and the ground selection line GSL. The ground selection line GSL may extend to penetrate the first memory cell array MCA1a and the second memory cell array MCA2a along the first direction D1.

For example, by using the plurality of word lines WL, the string selection line SSL, and the ground selection line GSL, read operations, program operations, and erase operations may be performed on the memory cell array MCA1a and MCA2a. For example, while performing one of the read, program, and erase operations, the plurality of string selection line pass transistors and the plurality of ground selection line pass transistors may control the operation of supplying voltage to the string selection line SSL and the ground selection line GSL through switching operations.

For example, in a cross-sectional view, the plurality of word lines WL, the string selection line SSL, and the ground selection line GSL may be formed in a step-shaped multi-layer structure PLSa. For example, the step-shaped multi-layer structure PLSa may be disposed in an X decoder area B.

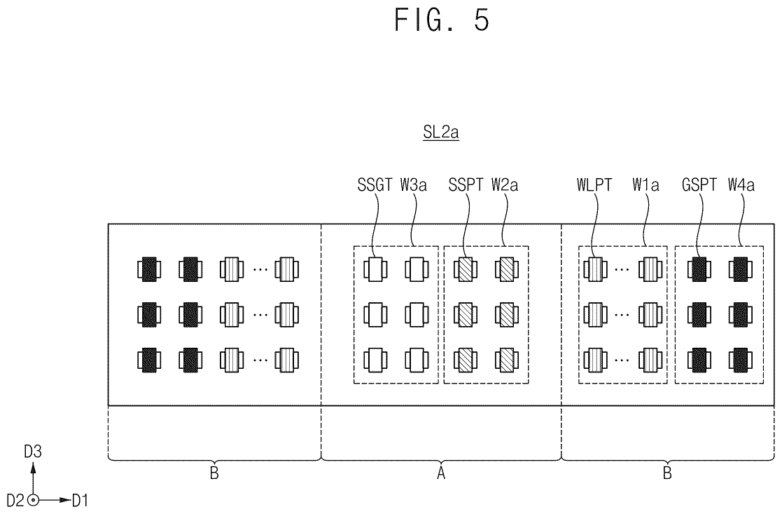

For example, a plurality of string selection line pass transistors SSPT or the plurality of ground selection line pass transistors GSPT may be formed in the X decoder region B. However, embodiments are not limited thereto. For example, as will be described with reference to FIGS. 5 to 8, the plurality of string selection line pass transistors SSPT and/or the plurality of ground selection line pass transistors GSPT may be formed in a cell array area A.

FIGS. 5, 6, 7, and 8 are plan views of examples of a second semiconductor layer included in a nonvolatile memory device according to one or more embodiments.

Referring to FIG. 5, a second semiconductor layer SL2a in which a third well W3a and a second well W2a are formed in a cell array area A is illustrated. In the third well W3a, a plurality of string selection line ground transistors SSGT may be formed, and in the second well W2a, a plurality of string selection line pass transistors SSPT may be formed. Hereinafter, description of aspects similar to those of FIG. 2 may be omitted.

For example, the second semiconductor layer SL2a may include a first well W1a, a second well W2a, a third well W3a, and a fourth well W4a. For example, a plurality of ground selection line pass transistors GSPT may be formed in the fourth well W4a.

In this case, the second well W2a and the third well W3a may be disposed adjacent to each other in the first direction D1. For example, the first well W1a and the fourth well W4a may be disposed adjacent to each other in the first direction D1. For example, the second well W2a and the third well W3a may be formed in the cell array area A, and the first well W1a and the fourth well W4a may be formed in an X decoder area B. Accordingly, the size of the X decoder area B may be further reduced compared to the case where the first, second, and fourth wells W1a, W2a, and W4a are formed in the X decoder area B.

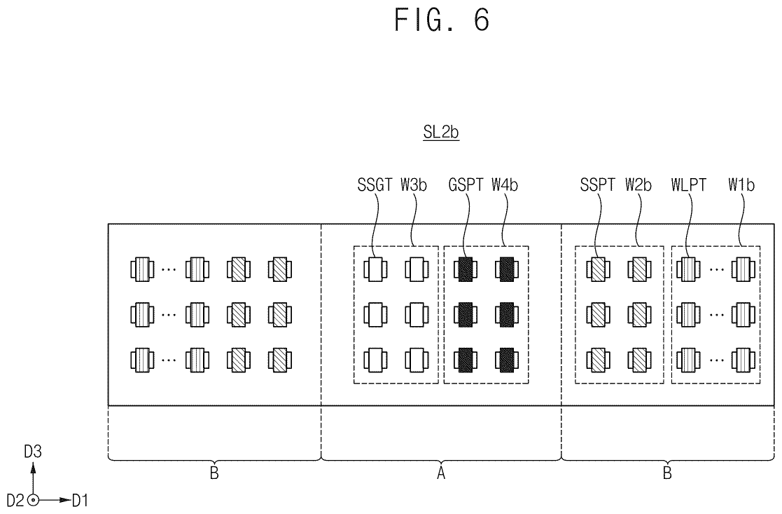

Referring to FIG. 6, a second semiconductor layer SL2b in which a third well W3b and a fourth well W4b are formed in a cell array area A is illustrated. Hereinafter, description of aspects similar to those of FIG. 2 may be omitted.

For example, the third well W3b and the fourth well W4b may be disposed adjacent to each other in the first direction D1. For example, the first well W1b and the second well W2b may be disposed adjacent to each other in the first direction D1. For example, the third well W3b and the fourth well W4b may be formed in the cell array area A, and the first well W1b and the second well W2b may be formed in an X decoder area B. Accordingly, the area of the X decoder area B may be further reduced compared to the case where the first, second, and fourth wells W1b, W2b, and W4b are formed in the X decoder area B.

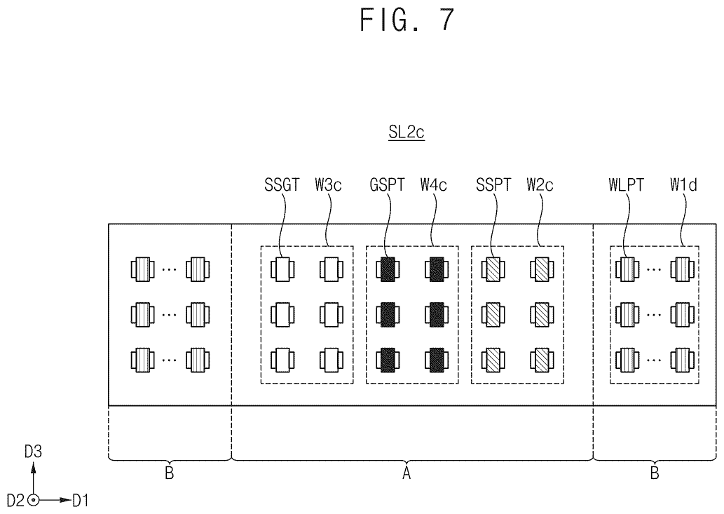

Referring to FIG. 7, a second semiconductor layer SL2c in which a second well W2c, a third well W3c, and a fourth well W4c are formed in a cell array area A is illustrated. Hereinafter, description of aspects similar to those of FIG. 2 may be omitted.

For example, the second well W2c, the third well W3c, and the fourth well W4c may be disposed adjacent to each other in the first direction D1. For example, the second well W2c, the third well W3c, and the fourth well W4c may be formed in the cell array area A, and the first well W1c may be formed in an X decoder area B. Accordingly, the area of the X decoder area B may be further reduced compared to the case where the first, second, and fourth wells W1c, W2c, and W4c are formed in the X decoder area B.

However, embodiments are not limited thereto, and a plurality of wells in which various pass transistors other than a plurality of word line pass transistors WLPT are formed may be formed in the cell array area A. In other words, only the first well W1c in which the plurality of word line pass transistors WLPT are formed may be formed in the X decoder area B.

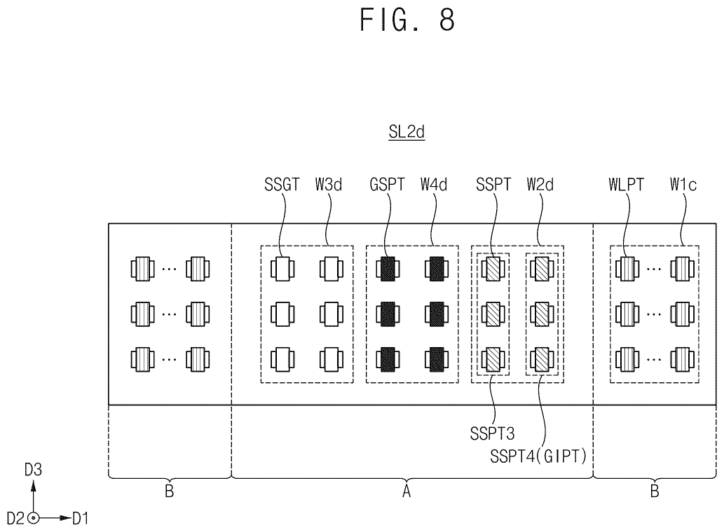

Referring to FIG. 8, a second semiconductor layer SL2d in which a second well W2d, a third well W3d, and a fourth well W4d are formed in a cell array area A may be illustrated. In the second well W2d, a plurality of string selection line pass transistors SSPT3 and SSPT4 may be formed. Hereinafter, description of aspects similar to those of FIG. 7 may be omitted.

For example, the plurality of string selection line pass transistors SSPT3 and SSPT4 may be formed in the second well W2d. For example, the plurality of string selection line pass transistors SSPT3 and SSPT4 may include third string selection line pass transistors SSPT3 and fourth string selection line pass transistors SSPT4. For example, the fourth string selection line pass transistors SSPT4 may be used as a plurality of gate induced drain leakage (GIDL) pass transistors GIPT that operate using the GIDL phenomenon. Accordingly, FIG. 8 illustrates an example in which a plurality of string selection line pass transistors SSPT, a plurality of ground selection line pass transistors GSPT, and the plurality of GIDL pass transistors GIPT are formed in the cell array area A.

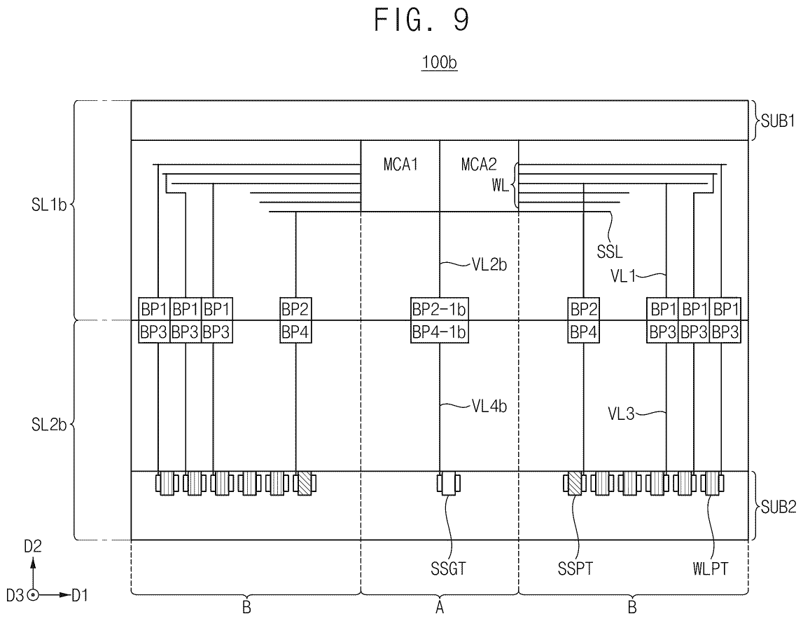

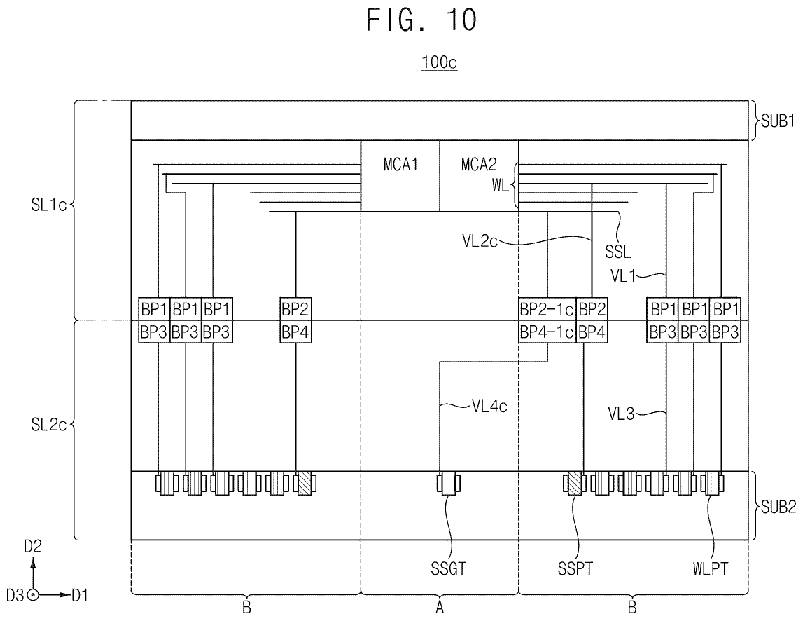

FIGS. 9 and 10 are cross-sectional views of examples of a nonvolatile memory device according to one or more embodiments.

Referring to FIG. 9, a nonvolatile memory device 100b may include a first semiconductor layer SL1b and a second semiconductor layer SL2b. Hereinafter, description of aspects similar to those of FIG. 1 may be omitted.

Compared to the first semiconductor layer SL1 in FIG. 1, the first semiconductor layer SL1b may further include a plurality of first vertical wires VL1b, a plurality of second vertical wires VL2b, a plurality of first bonding pads BP1, and a plurality of second bonding pads BP2 and BP2-1b.

Compared to the second semiconductor layer SL2 in FIG. 1, the second semiconductor layer SL2b may further include a plurality of third vertical wires VL3b, a plurality of fourth vertical wires VL4b, a plurality of third bonding pads BP3, and a plurality of fourth bonding pads BP4 and BP4-1b.

For example, a plurality of word lines WL may be connected to the plurality of first vertical wires VL1b and the plurality of first bonding pads BP1. For example, the plurality of first bonding pads BP1 may be bonded to and electrically connected to the plurality of third bonding pads BP3. For example, the plurality of third vertical wires VL3b and the plurality of third bonding pads BP3 may be connected to the plurality of word line pass transistors WLPT.

Likewise, a string selection line SSL may be connected to the plurality of second vertical wires VL2b and the plurality of second bonding pads BP2 and BP2-1b. For example, the plurality of second bonding pads BP2 and BP2-1b may be bonded and electrically connected to the plurality of fourth bonding pads BP4 and BP4-1b.

For example, the first and second semiconductor layers SL1b and SL2b may be electrically connected by the plurality of first to fourth bonding pads BP1, BP2, BP2-1b, BP3, BP4, and BP4-1b.

For example, a second-first bonding pad BP2-1b connected to the string selection line SSL and a fourth-first bonding pad BP4-1b connected to a plurality of string selection line ground transistors SSGT may be disposed in a cell array area A. For example, the second-first bonding pad BP2-1b and the fourth-first bonding pad BP4-1b may be disposed adjacent to the boundary (e.g., the center of the cell array area A) of the first and second memory cell arrays MCA1 and MCA2.

Referring to FIG. 10, a nonvolatile memory device 100c may include a first semiconductor layer SL1c and a second semiconductor layer SL2c. Hereinafter, description of aspects similar to those of FIGS. 1 and 9 may be omitted.

Compared to the first semiconductor layer SL1 in FIG. 1, the first semiconductor layer SL1c may further include a plurality of first vertical wires VL1c, a plurality of second vertical wires VL2c, a plurality of first bonding pads BP1, and a plurality of second bonding pads BP2 and BP2-1c.

Compared to the second semiconductor layer SL2 in FIG. 1, the second semiconductor layer SL2c may further include a plurality of third vertical wires VL3c, a plurality of fourth vertical wires VL4c, a plurality of third bonding pads BP3, and a plurality of fourth bonding pads BP4 and BP4-1c.

For example, the first and second semiconductor layers SL1c and SL2c may be electrically connected by the plurality of first to fourth bonding pads BP1, BP2, BP2-1c, BP3, BP4, and BP4-1c.

For example, a second-first bonding pad BP2-1c connected to a string selection line SSL and a fourth-first bonding pad BP4-1c connected to a plurality of string selection line ground transistors SSGT may be disposed in an X decoder area B. For example, the second-first bonding pad BP2-1c and the fourth-first bonding pad BP4-1c may be disposed as close to a cell array area A as possible within the X decoder area B.

FIG. 11 is a block diagram illustrating a nonvolatile memory device according to one or more embodiments.

Referring to FIG. 11, a nonvolatile memory device 500 may be an example of the nonvolatile memory device 100 in FIG. 1. The nonvolatile memory device 500 may include a memory cell array 510, an address decoder 520, a page buffer circuit 530, a data input/output (I/O) circuit 540, a voltage generator 550 and a control circuit 560.

The nonvolatile memory device 500 may have the above-described BVNAND structure. In one or more embodiments, the memory cell array 510 may be formed in the first semiconductor layer SL1 in FIG. 1, and the address decoder 520, the page buffer circuit 530, the data I/O circuit 540, the voltage generator 550 and the control circuit 560 may be formed in the second semiconductor layer SL2 in FIG. 1. In this case, the address decoder 520, the page buffer circuit 530, the data I/O circuit 540, the voltage generator 550 and the control circuit 560 may represent the peripheral circuit 501.

The memory cell array 510 may be connected to the address decoder 520 via a plurality of string selection lines SSL, a plurality of word lines WL and a plurality of ground selection lines GSL. The memory cell array 510 may be further connected to the page buffer circuit 530 via a plurality of bitlines BL. The memory cell array 510 may include a plurality of memory cells (e.g., a plurality of nonvolatile memory cells) that are connected to the plurality of word lines WL and the plurality of bitlines BL. The memory cell array 510 may be divided into a plurality of memory blocks BLK1, BLK2, . . . , BLKz (z being any positive integer) each of which includes memory cells. In addition, each of the plurality of memory blocks BLK1, BLK2, . . . , BLKz may be divided into a plurality of pages.

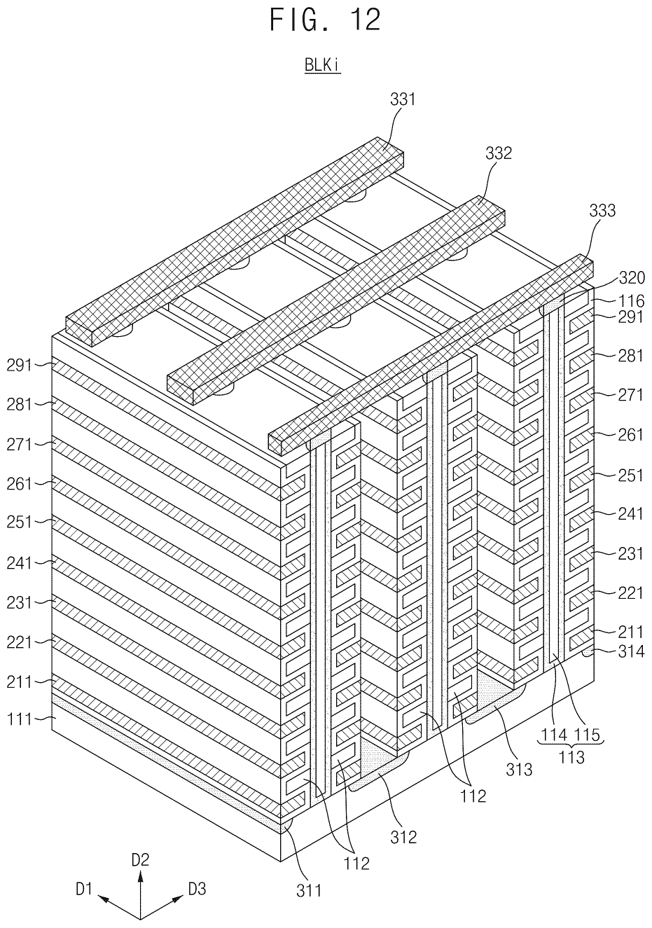

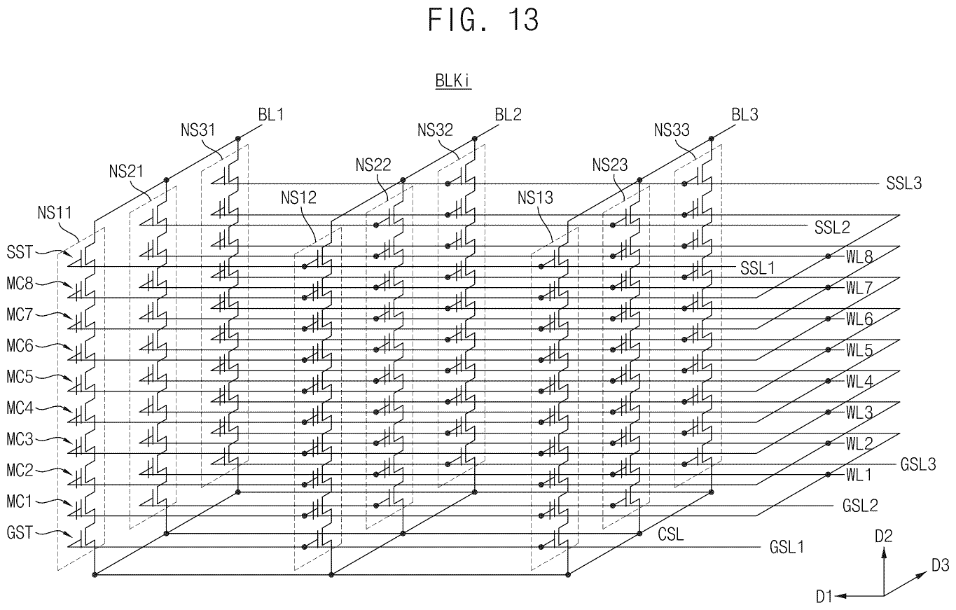

In one or more embodiments, as will be described with reference to FIGS. 12 and 13, the memory cell array 510 may be a three-dimensional memory cell array, which is formed on a substrate in a three-dimensional structure (or a vertical structure). The memory cell array 510 may include a plurality of cell strings (e.g., a plurality of vertical NAND strings) that are vertically oriented such that at least one memory cell is located over another memory cell.

The control circuit 560 may receive a command CMD and an address ADDR from an outside (e.g., from a host device and/or a memory controller), and control erasure, programming and read operations of the nonvolatile memory device 500 based on the command CMD and the address ADDR. An erasure operation may include performing a sequence of erase loops, and a program operation may include performing a sequence of program loops. Each program loop may include a program operation and a program verification operation. Each erase loop may include an erase operation and an erase verification operation. The read operation may include a normal read operation and data recover read operation.

In one or more embodiments, the control circuit 560 may generate control signals CON, which are used for controlling the voltage generator 550, and may generate control signal PBC for controlling the page buffer circuit 530, based on the command CMD, and may generate a row address R_ADDR and a column address C_ADDR based on the address ADDR. The control circuit 560 may provide the row address R_ADDR to the address decoder 520 and may provide the column address C_ADDR to the data I/O circuit 540.

The address decoder 520 may be connected to the memory cell array 510 via the plurality of string selection lines SSL, the plurality of word lines WL and the plurality of ground selection lines GSL. In one or more embodiments, in the data erase/write/read operations, the address decoder 520 may determine at least one of the plurality of word lines WL as a selected word line, may determine at least one of the plurality of string selection lines SSL as a selected string selection line, and may determine at least one of the plurality of ground selection lines GSL as a selected ground selection line, based on the row address R_ADDR.

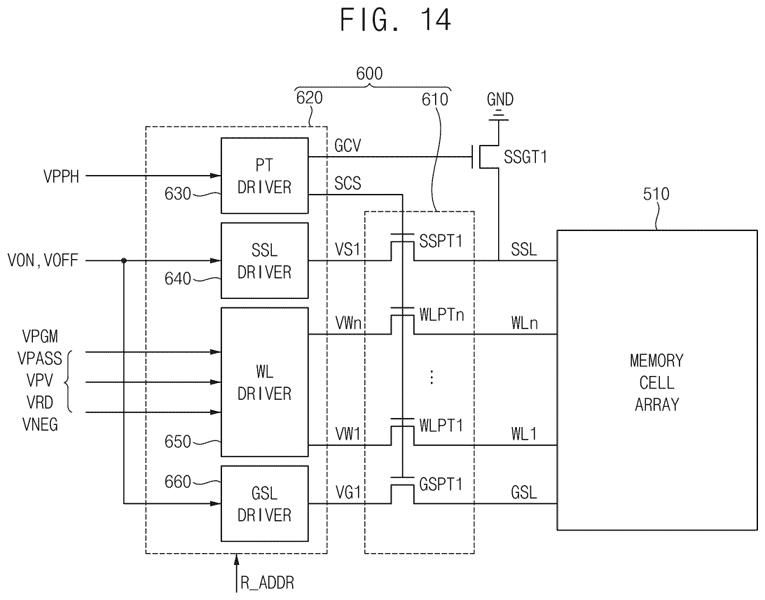

The address decoder 520 may include a plurality of pass transistors (PT) 522 and a plurality of drivers (DRV) 524. Detailed configurations of the plurality of pass transistors 522 and the plurality of drivers 524 will be described with reference to FIG. 14.

The voltage generator 550 may generate voltages VS that are used for an operation of the nonvolatile memory device 500 based on a power PWR and the control signals CON. The voltages VS may be applied to the plurality of string selection lines SSL, the plurality of word lines WL and the plurality of ground selection lines GSL via the address decoder 520. In addition, the voltage generator 550 may generate an erase voltage VERS that is used for the data erase operation based on the power PWR and the control signals CON.

The page buffer circuit 530 may be connected to the memory cell array 510 via the plurality of bitlines BL. The page buffer circuit 530 may include a plurality of page buffers. The page buffer circuit 530 may store data DAT to be programmed into the memory cell array 510 or may read data DAT sensed from the memory cell array 510. In other words, the page buffer circuit 530 may operate as a write driver or a sensing amplifier according to an operation mode of the nonvolatile memory device 500.

The data I/O circuit 540 may be connected to the page buffer circuit 530 via data lines DL. The data I/O circuit 540 may provide the data DAT from an outside of the nonvolatile memory device 500 to the memory cell array 510 via the page buffer circuit 530 or may provide the data DAT from the memory cell array 510 to the outside of the nonvolatile memory device 500, based on the column address C_ADDR.

FIG. 12 is a perspective view of an example of a memory block included in a memory cell array of a nonvolatile memory device according to one or more embodiments.

Referring to FIG. 12, a memory block BLKi may include a plurality of cell strings (e.g., a plurality of vertical NAND strings) which are formed on a substrate in a three-dimensional structure (or a vertical structure). The memory block BLKi may include structures extending along the first, second and third directions D1, D2 and D3.

A substrate 111 (e.g., the upper substrate of the first semiconductor layer SL1) may be provided. In one or more embodiments, the substrate 111 may have a well of a first type of charge carrier impurity (e.g., a first conductivity type) therein. In one or more embodiments, the substrate 111 may have a p-well formed by implanting a group 3 element such as boron (B). The substrate 111 may have a pocket p-well provided within an n-well. In one or more embodiments, the substrate 111 has a p-type well (or a p-type pocket well). However, the conductive type of the substrate 111 is not limited to p-type.

A plurality of doping regions 311, 312, 313 and 314 arranged along the third direction D3 are provided in/on the substrate 111. These plurality of doping regions 311 to 314 may have a second type of charge carrier impurity (e.g., a second conductivity type) different from the first type of the substrate 111. In one or more embodiments, the first to fourth doping regions 311 to 314 may have n-type. However, the conductive type of the first to fourth doping regions 311 to 314 is not limited to n-type.

A plurality of insulation materials 112 extending along the first direction D1 may be sequentially provided along the second direction D2 on a region of the substrate 111 between the first and second doping regions 311 and 312. In one or more embodiments, the plurality of insulation materials 112 may be provided along the second direction D2, being spaced by a specific distance. In one or more embodiments, the insulation materials 112 may include an insulation material such as an oxide layer.

A plurality of pillars 113 penetrating the insulation materials along the second direction D2 may be sequentially disposed along the first direction D1 on a region of the substrate 111 between the first and second doping regions 311 and 312. In one or more embodiments, the plurality of pillars 113 may penetrate the insulation materials 112 to contact the substrate 111.

In one or more embodiments, each pillar 113 may include a plurality of materials. In one or more embodiments, a channel layer 114 of each pillar 113 may include a silicon material having a first conductivity type. In one or more embodiments, the channel layer 114 of each pillar 113 may include a silicon material having the same conductivity type as the substrate 111. In one or more embodiments, the channel layer 114 of each pillar 113 includes p-type silicon. However, the channel layer 114 of each pillar 113 is not limited to the p-type silicon.

An internal material 115 of each pillar 113 may include an insulation material. In one or more embodiments, the internal material 115 of each pillar 113 may include an insulation material such as a silicon oxide. In one or more embodiments, the internal material 115 of each pillar 113 may include an air gap. The term “air” may refer to atmospheric air, or other gases that may be present during the manufacturing process.

An insulation layer 116 may be provided along the exposed surfaces of the insulation materials 112, the pillars 113, and the substrate 111, on a region between the first and second doping regions 311 and 312. In one or more embodiments, the insulation layer 116 provided on surfaces of the insulation material 112 may be interposed between pillars 113 and a plurality of stacked first conductive materials 211, 221, 231, 241, 251, 261, 271, 281 and 291, as illustrated. In one or more embodiments, the insulation layer 116 need not be provided between the first conductive materials 211 to 291 corresponding to ground selection lines GSL (e.g., 211) and string selection lines SSL (e.g., 291). The ground selection lines GSL may be the lowermost ones of the stack of first conductive materials 211 to 291 and the string selection lines SSL are the uppermost ones of the stack of first conductive materials 211 to 291.

The plurality of first conductive materials 211 to 291 may be provided on surfaces of the insulation layer 116, in a region between the first and second doping regions 311 and 312. In one or more embodiments, the first conductive material 211 extending along the first direction D1 may be provided between the insulation material 112 adjacent to the substrate 111 and the substrate 111. The first conductive material 211 extending along the first direction D1 may be provided between the insulation layer 116 at the bottom of the insulation material 112 adjacent to the substrate 111 and the substrate 111.

A first conductive material extending along the first direction D1 may be provided between the insulation layer 116 at the top of the specific insulation material among the insulation materials 112 and the insulation layer 116 at the bottom of a specific insulation material among the insulation materials 112. In one or more embodiments, a plurality of first conductive materials 221 to 281 extending along the first direction D1 may be provided between the insulation materials 112 and the insulation layer 116 may be provided between the insulation materials 112 and the first conductive materials 221 to 281. The first conductive materials 211 to 291 may be formed of a conductive metal, and the first conductive materials 211 to 291 may include a conductive material such as a polysilicon.

The same structures as those on the first and second doping regions 311 and 312 may be provided in a region between the second and third doping regions 312 and 313. In the region between the second and third doping regions 312 and 313, a plurality of insulation materials 112 may be provided, which extend along the first direction D1. A plurality of pillars 113 may be provided that are disposed sequentially along the first direction D1 and penetrate the plurality of insulation materials 112 along the second direction D2. An insulation layer 116 may be provided on the exposed surfaces of the plurality of insulation materials 112 and the plurality of pillars 113, and a plurality of first conductive materials 211 to 291 extend along the first direction D1. Similarly, the same structures as those on the first and second doping regions 311 and 312 may be provided in a region between the third and fourth doping regions 313 and 314.

A plurality of drain regions 320 may be provided on the plurality of pillars 113, respectively. The drain regions 320 may include silicon materials doped with a second type of charge carrier impurity. In one or more embodiments, the drain regions 320 may include silicon materials doped with an n-type dopant. In one or more embodiments, the drain regions 320 include n-type silicon materials. However, the drain regions 320 are not limited to n-type silicon materials.

On the drain regions, a plurality of second conductive materials 331, 332 and 333 may be provided, which extend along the third direction D3. The second conductive materials 331 to 333 may be disposed along the first direction D1, being spaced apart from each other by a specific distance. The second conductive materials 331 to 333 may be respectively connected to the drain regions 320 in a corresponding region. The drain regions 320 and the second conductive material 333 extending along the third direction D3 may be connected through each contact plug. Each contact plug may be, in one or more embodiments, a conductive plug formed of a conductive material such as a metal. The second conductive materials 331 to 333 may include metal materials. The second conductive materials 331 to 333 may include conductive materials such as a polysilicon.

The first conductive materials 211 to 291 may be used to form the word lines WL, the string selection lines SSL and the ground selection lines GSL. In one or more embodiments, the first conductive materials 221 to 281 may be used to form the word lines WL, where conductive materials belonging to the same layer may be interconnected. The second conductive materials 331 to 333 may be used to form the bitlines BL. The number of layers of the first conductive materials 211 to 291 may be changed variously according to process and control techniques.

FIG. 13 is a circuit diagram illustrating an equivalent circuit of a memory block according to one or more embodiment.

A memory block BLKi of FIG. 13 may be formed on a substrate in a three-dimensional structure (or a vertical structure). In one or more embodiments, a plurality of NAND strings included in the memory block BLKi may be formed in a direction perpendicular to the substrate.

Referring to FIG. 13, the memory block BLKi may include a plurality of NAND strings NS11, NS12, NS13, NS21, NS22, NS23, NS31, NS32 and NS33 connected between bitlines BL1, BL2 and BL3 and a common source line CSL. Each of the NAND strings NS11 to NS33 may include a string selection transistor SST, a plurality of memory cells MC1, MC2, MC3, MC4, MC5, MC6, MC7 and MC8, and a ground selection transistor GST. In one or more embodiments, the bitlines BL1 to BL3 may correspond to the second conductive materials 331 to 333 in FIG. 12, and the common source line CSL may be formed by interconnecting the first to fourth doping regions 311 to 314 in FIG. 12.

Each string selection transistor SST may be connected to a corresponding string selection line (one of SSL1, SSL2 and SSL3). The plurality of memory cells MC1 to MC8 may be connected to corresponding word lines WL1, WL2, WL3, WL4, WL5, WL6, WL7 and WL8, respectively. Each ground selection transistor GST may be connected to a corresponding ground selection line (one of GSL1, GSL2 and GSL3). Each string selection transistor SST may be connected to a corresponding bitline (e.g., one of BL1 to BL3), and each ground selection transistor GST may be connected to the common source line CSL. In the example of FIG. 13, some of the string selection transistors SST may be connected to the same bitline (e.g., one of BL1 to BL3) to connect corresponding NAND strings to the same bitline up appropriate selection via selection voltages applied to the appropriate string selection lines SSL1 to SSL3 and ground selection lines GSL1 to GSL3.

The cell strings connected in common to one bitline may form one column, and the cell strings connected to one string selection line may form one row. In one or more embodiments, the cell strings NS11, NS21 and NS31 connected to the first bitline BL1 may correspond to a first column, and the cell strings NS11, NS12 and NS13 connected to the first string selection line SSL1 may form a first row.

Wordlines (e.g., WL1) having the same height may be commonly connected, and the ground selection lines GSL1 to GSL3 and the string selection lines SSL1 to SSL3 may be separated. Memory cells located at the same semiconductor layer share a word line. Cell strings in the same row share a string selection line. The common source line CSL is connected in common to all of cell strings.

In FIG. 13, the memory block BLKi is illustrated to be connected to eight word lines WL1 to WL8 and three bitlines BL1 to BL3, and each of the NAND strings NS11 to NS33 is illustrated to include eight memory cells MC1 to MC8. However, embodiments are not limited thereto. In one or more embodiments, each memory block may be connected to any number of word lines and bitlines, and each NAND string may include any number of memory cells.

A three-dimensional vertical array structure may include vertical NAND strings that are vertically oriented such that at least one memory cell is located over another memory cell. The at least one memory cell may include a charge trap layer.

Although the memory cell array included in the nonvolatile memory device according to one or more embodiments is described based on a NAND flash memory device, the nonvolatile memory device according to one or more embodiments may be any nonvolatile memory device, such as a phase-change random access memory (PRAM), a resistive random access memory (RRAM), a nano floating gate memory (NFGM), a polymer random access memory (PoRAM), a magnetic random access memory (MRAM), a ferroelectric random access memory (FRAM), a thyristor random access memory (TRAM), etc.

FIG. 14 is a block diagram illustrating an example of an address decoder included in a nonvolatile memory device according to one or more embodiments.

Referring to FIG. 14, an address decoder 600 may be connected to the memory cell array 510 through a string selection line SSL, word lines WL1, . . . , WLn, and a ground selection line GSL, and may include a pass switch circuit 610, a driver circuit 620, and a string selection line ground transistor SSGT1. The address decoder 600 may be referred to as a row decoder, a word line decoder, or the like.

The pass switch circuit 610 may include a plurality of pass transistors SSPT1, WLPT1, . . . , WLPTn, and GSPT1. For example, the plurality of pass transistors SSPT1, WLPT1 to WLPTn and GSPT1 may include a string selection line pass transistor SSPT1 connected to the string selection line SSL, word line pass transistors WLPT1 to WLPTn connected to the word lines WL1 to WLn, and a ground selection line pass transistor GSPT1 connected to the ground selection line GSL.

The driver circuit 620 may control switching operations of the plurality of pass transistors SSPT1, WLPT1 to WLPTn and GSPT1, and may control operations of supplying voltages VS1, VW1, . . . , VWn and VG1 to the memory cell array 510 through the plurality of pass transistors SSPT1, WLPT1 to WLPTn and GSPT1. The driver circuit 620 may include a pass transistor driver 630, a string selection line driver 640, a word line driver 650 and a ground selection line driver 660. For example, the driver circuit 620 may be disposed in the X decoder area B of FIG. 1. That is, the pass transistor driver 630, the string selection line driver 640, the word line driver 650, and the ground selection line driver 660 may all be disposed in the X decoder area B of FIG. 1.

The pass transistor driver 630 may generate a plurality of switching control signals SCS based on a high-voltage VPPH provided from a voltage generator (e.g., the voltage generator 550 in FIG. 11). The plurality of switching control signals SCS may be applied to gate electrodes of the plurality of pass transistors SSPT1, WLPT1 to WLPTn and GSPT1. The switching operations of the plurality of pass transistors SSPT1, WLPT1 to WLPTn and GSPT1 may be controlled in response to the plurality of switching control signals SCS. The timing at which the voltages VS1, VW1 to VWn and VG1 are applied to the memory cell array 510 may be controlled by the switching operations of the plurality of pass transistors SSPT1, WLPT1 to WLPTn and GSPT1.

For example, the pass transistor driver 630 may generate a ground control signal GCV to control operations of the string selection line ground transistor SSGT1. The ground control signal GCV may be applied to the gate electrode of the string selection line ground transistor SSGT1. The string selection line ground transistor SSGT1 may supply a low voltage to the string selection line SSL in response to the ground control signal GCV. For example, the string selection line ground transistor SSGT1 may supply a ground voltage GND to discharge an unselected string.

The plurality of pass transistors SSPT1, WLPT1 to WLPTn and GSPT1 may be implemented such that the string selection line SSL the word lines WL1 to WLn, and the ground selection line GSL are electrically connected to the string selection line driver 640, the word line driver 650 and the ground selection line driver 660, respectively, in response to activations of the plurality of switching control signals SCS. For example, the plurality of switching control signals SCS may be generated based on the high-voltage VPPH and may have a voltage level corresponding to the high-voltage VPPH, and thus the plurality of pass transistors SSPT1, WLPT1 to WLPTn and GSPT1 may include a high-voltage transistor capable of enduring the high-voltage.

The string selection line driver 640 may output one of an on-voltage VON and an off-voltage VOFF provided from the voltage generator as a string selection voltage VS. When the string pass transistor SSPT1 is turned on, the string selection voltage VS1 may be applied to the memory cell array 510 through the string selection line SSL. When the string pass transistor SSPT1 is turned on, the string selection voltage VS1 may be applied to the memory cell array 510 through the string selection line SSL. For example, during a program operation, the string selection line driver 640 may supply the string selection voltage VS1 so as to turn on all string selection transistors in a selected memory block.

The word line driver 650 may output one of a program voltage VPGM, a pass voltage VPASS, a verification voltage VPV, a read voltage VRD and a negative voltage VNEG provided from the voltage generator to a respective one of the word lines WL1 to WLn, according to an operation of a nonvolatile memory device (e.g., the nonvolatile memory device 500 of FIG. 11). When one of the word line pass transistors WLPT1 to WLPTn are turned on, a respective one of word line voltages VW1 to VWn may be provided to the memory cell array 510 through a respective one of the word lines WL1 to WLn.

The ground selection line driver 660 may output one of the on-voltage VON and the off-voltage VOFF provided from the voltage generator as a ground selection voltage VG1. When the ground pass transistor GSPT1 is turned on, the ground selection voltage VG1 may be applied to the memory cell array 510 through the ground selection line GSL.

In one or more embodiments, each of the pass transistor driver 630, the string selection line driver 640, the word line driver 650, and the ground selection line driver 660 may include a plurality of sub-drivers that control a part or portion of the memory cell array 510. In one or more embodiments, the address decoder 600 may operate based on the row address R_ADDR.

In one or more embodiments, a plurality of word line pass transistors WLPT1 to WLPTn connected to the word lines WL1 to WLn, an string selection line pass transistor SSPT1 connected to the string selection line SSL, and an string selection line ground transistor SSGT1 connected to the string selection line SSL may be a plurality of word line pass transistors, a plurality of string selection line pass transistors, and a plurality of string selection line ground transistors according to embodiments described above with reference to FIGS. 1 to 10.

For example, the string selection line ground transistor SSGT1 may be disposed in the cell array area A of FIG. 1, and the plurality of word line pass transistors WLPT1 to WLPTn and the string selection line pass transistor SSPT1 may be disposed in the X decoder area B of FIG. 1.

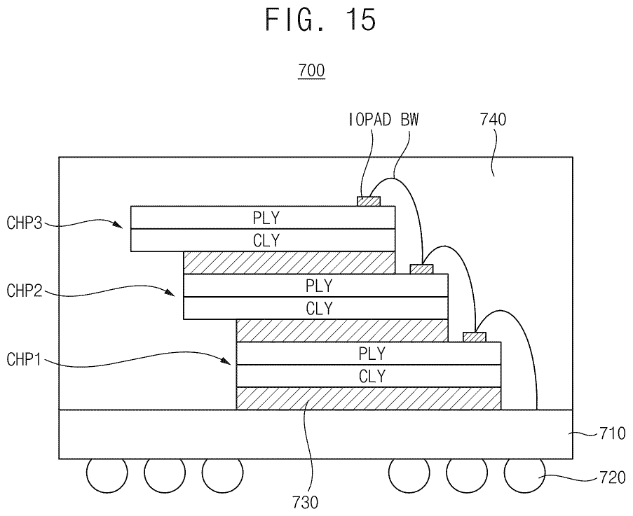

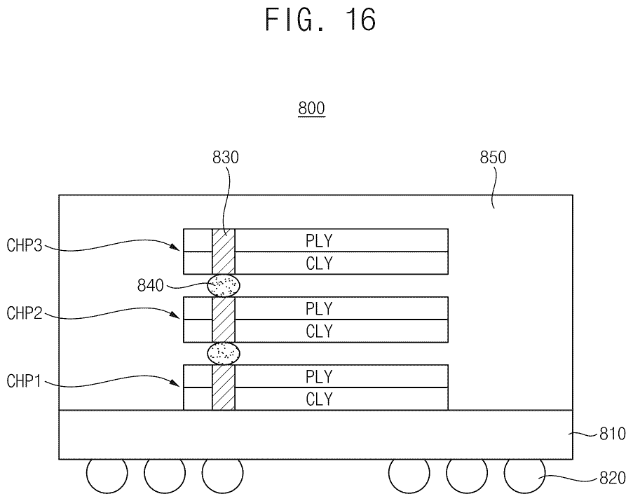

FIGS. 15 and 16 are cross-sectional views of a memory package including a nonvolatile memory device according to one or more embodiments.

Referring to FIG. 15, a memory package 700 may include a base substrate 710 and a plurality of memory chips CHP1, CHP2 and CHP3 stacked on the base substrate 710.

Each of the memory chips CHP1 to CHP3 may include a memory cell layer CLY and a peripheral circuit layer PLY, and may further include a plurality of I/O pads IOPAD. The memory cell layer CLY and the peripheral circuit layer PLY may correspond to the first semiconductor layer SL1 and the second semiconductor layer SL2 described with reference to FIG. 1, respectively, and further may include said elements described herein to be included in the first semiconductor layer SL1 and the second semiconductor layer SL2, respectively. Each of the memory chips CHP1 to CHP3 may include the memory device according to one or more embodiments.

In one or more embodiments, the memory chips CHP1 to CHP3 may be stacked on the base substrate 710 such that a surface on which the plurality of I/O pads IOPAD are formed faces upwards. In one or more embodiments, with respect to each of the memory chips CHP1 to CHP3, the plurality of I/O pads IOPAD may be arranged near one side of the semiconductor substrate. As such, the memory chips CHP1 to CHP3 may be stacked in a step shape, such that the plurality of I/O pads IOPAD of each memory chip may be exposed. In such stacked state, the memory chips CHP1 to CHP3 may be electrically connected to the base substrate 710 through a plurality of bonding wires BW.

The stacked memory chips CHP1 to CHP3 and the plurality of bonding wires BW may be fixed by a sealing member 740, and adhesive members 730 may intervene between the base substrate 710 and the memory chips CHP1 to CHP3. Conductive bumps 720 may be formed on a bottom surface of the base substrate 710 for electrical connections to an external device.

Referring to FIG. 16, a memory package 800 may include a base substrate 810 and the plurality of memory chips CHP1 to CHP3 stacked on the base substrate 810. The description of aspects similar to those of FIG. 15 may be omitted.

Each of the memory chips CHP1 to CHP3 may include the memory cell layer CLY and the peripheral circuit layer PLY, and may further include a plurality of through silicon vias (TSVs) 830.

In one or more embodiments, with respect to each of the memory chips CHP1 to CHP3, the plurality of TSVs 830 may be arranged at the same locations in each memory chip. As such, the memory chips CHP1 to CHP3 may be stacked such that the plurality of TSVs 830 of each memory chip may be completely overlapped (e.g., arrangements of the plurality of TSVs 830 may be perfectly matched in the memory chips CHP1 to CHP3). In such stacked state, the memory chips CHP1 to CHP3 may be electrically connected to one another and the base substrate 810 through the plurality of TSVs 830 and conductive material 840.

Conductive bumps 820 and a sealing member 850 may be substantially the same as the conductive bumps 720 and the sealing member 740 in FIG. 15.

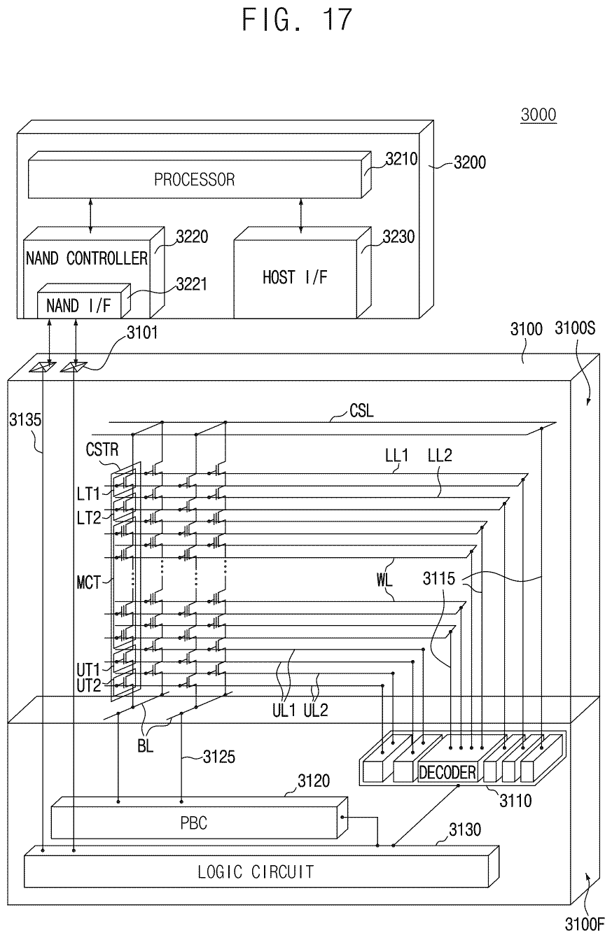

FIG. 17 is a block diagram illustrating an electronic system including a nonvolatile memory device according to one or more embodiments.

Referring to FIG. 17, an electronic system 3000 may include a semiconductor device 3100 and a controller 3200 electrically connected to the semiconductor device 3100. The electronic system 3000 may be a storage device including one or a plurality of semiconductor devices 3100 or an electronic device including the storage device. For example, the electronic system 3000 may be a solid state drive (SSD) device, a universal serial bus (USB), a computing system, a medical device, or a communication device that may include one or a plurality of semiconductor devices 3100.

The semiconductor device 3100 may be a memory device, for example, a nonvolatile memory device according to one or more embodiments described with reference to FIG. 1. The semiconductor device 3100 may include a first structure 3100F and a second structure 3100S on the first structure 3100F. The first structure 3100F may be a peripheral circuit structure including a decoder circuit 3110, a page buffer circuit 3120, and a logic circuit 3130. The second structure 3100S may be a memory cell structure including bitlines BL, a common source line CSL, word lines WL, first and second upper gate lines UL1 and UL2, first and second lower gate lines LL1 and LL2, and memory cell strings CSTR between the bitlines BL and the common source line CSL.

In the second structure 3100S, each of the memory cell strings CSTR may include lower transistors LT1 and LT2 adjacent to the common source line CSL, upper transistors UT1 and UT2 adjacent to the bitlines BL, and a plurality of memory cell transistors MCT between the lower transistors LT1 and LT2 and the upper transistors UT1 and UT2. The number of the lower transistors LT1 and LT2 and the number of the upper transistors UT1 and UT2 may be changed according to one or more embodiments.

In one or more embodiments, the upper transistors UT1 and UT2 may include string selection transistors, and the lower transistors LT1 and LT2 may include ground selection transistors. The lower gate lines LL1 and LL2 may be gate electrodes of the lower transistors LT1 and LT2, respectively. The word lines WL may be gate electrodes of the memory cell transistors MCT, respectively, and the upper gate lines UL1 and UL2 may be gate electrodes of the upper transistors UT1 and UT2, respectively.

In one or more embodiments, the lower transistors LT1 and LT2 may include a lower erase control transistor LT1 and a ground selection transistor LT2 that may be connected with each other in serial. The upper transistors UT1 and UT2 may include a string selection transistor UT1 and an upper erase control transistor UT2. At least one of the lower erase control transistor LT1 and the upper erase control transistor UT2 may be used in an erase operation for erasing data stored in the memory cell transistors MCT by a GIDL phenomenon.

The common source line CSL, the first and second lower gate lines LL1 and LL2, the word lines WL, and the first and second upper gate lines UL1 and UL2 may be electrically connected to the decoder circuit 3110 through first connection wirings 3115 extending to the second structure 3110S in the first structure 3100F. The bitlines BL may be electrically connected to the page buffer circuit 3120 through second connection wirings 3125 extending to the second structure 3100S in the first structure 3100F.

In the first structure 3100F, the decoder circuit 3110 and the page buffer circuit 3120 may perform a control operation for at least one selected memory cell transistor among the plurality of memory cell transistors MCT. The decoder circuit 3110 and the page buffer circuit 3120 may be controlled by the logic circuit 3130. The semiconductor device 3100 may communicate with the controller 3200 through an input/output pad 3101 electrically connected to the logic circuit 3130. The input/output pad 3101 may be electrically connected to the logic circuit 3130 through an input/output connection wiring 3135 extending to the second structure 3100S in the first structure 3100F.

The controller 3200 may include a processor 3210, a NAND controller 3220, and a host interface 3230. The electronic system 3000 may include a plurality of semiconductor devices 3100, and in this case, the controller 3200 may control the plurality of semiconductor devices 3100.

The processor 3210 may control operations of the electronic system 3000 including the controller 3200. The processor 3210 may be operated by firmware, and may control the NAND controller 3220 to access the semiconductor device 3100. The NAND controller 3220 may include a NAND interface 3221 for communicating with the semiconductor device 3100. Through the NAND interface 3221, control command for controlling the semiconductor device 3100, data to be written in the memory cell transistors MCT of the semiconductor device 3100, data to be read from the memory cell transistors MCT of the semiconductor device 3100, etc., may be transferred. The host interface 3230 may provide communication between the electronic system 3000 and an outside host. When control command is received from the outside host through the host interface 3230, the processor 3210 may control the semiconductor device 3100 in response to the control command.

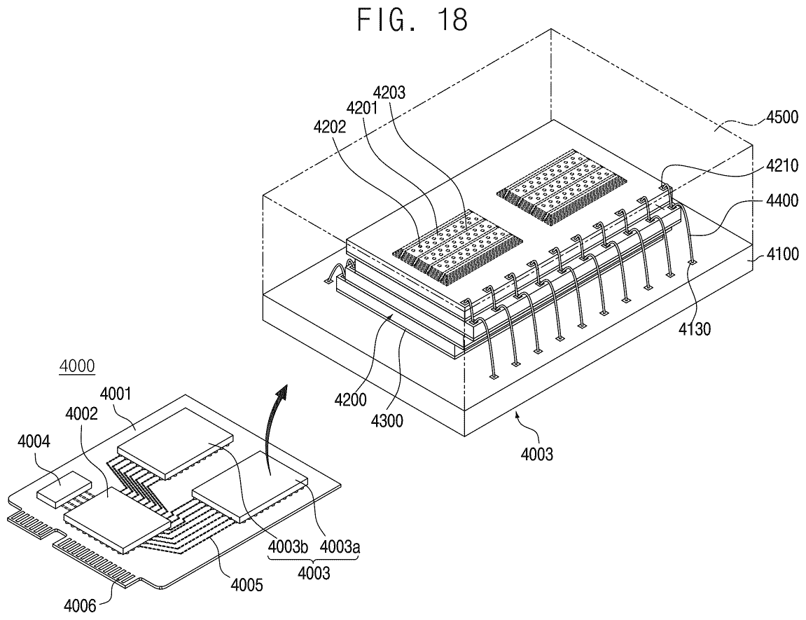

FIG. 18 is a perspective view of an electronic system including a nonvolatile memory device according to one or more embodiments.

Referring to FIG. 18, an electronic system 4000 may include a main substrate 4001, a controller 4002 mounted on the main substrate 4001, at least one semiconductor package 4003, and a dynamic random access memory (DRAM) device 4004. The semiconductor package 4003 and the DRAM device 4004 may be connected to the controller 4002 by wiring patterns 4005 on the main substrate 4001.

The main substrate 4001 may include a connector 4006 having a plurality of pins connected to an external host. The number and layout of the plurality pins in the connector 4006 may be changed depending on a communication interface between the electronic system 4000 and the external host. In one or more embodiments, the electronic system 4000 may communicate with the external host based on one of a USB, peripheral component interconnect express (PCIe), serial advanced technology attachment (SATA), M-PHY for universal flash storage (UFS), or the like. In one or more embodiments, the electronic system 4000 may be driven or may operate by a power source provided from the external host through the connector 4006. The electronic system 4000 may further include a power management integrated circuit (PMIC) for distributing the power source provided from the external host to the controller 4002 and the semiconductor package 4003.

The controller 4002 may write data in the semiconductor package 4003 or read data from the semiconductor package 4003, and may enhance an operation speed of the electronic system 4000.

The DRAM device 4004 may be a buffer memory for reducing the speed difference between the semiconductor package 4003 for storing data and the external host. The DRAM device 4004 included in the electronic system 4000 may serve as a cache memory, and may provide a space for temporarily storing data during the control operation for the semiconductor package 4003. When the electronic system 4000 includes the DRAM device 4004, the controller 4002 may further include a DRAM controller for controlling the DRAM device 4004 in addition to the NAND controller for controlling the semiconductor package 4003.

The semiconductor package 4003 may include first and second semiconductor packages 4003a and 4003b spaced apart from each other. The first and second semiconductor packages 4003a and 4003b may be semiconductor packages each of which includes a plurality of semiconductor chips 4200. Each of the first and second semiconductor packages 4003a and 4003b may include a package substrate 4100, the semiconductor chips 4200, bonding layers 4300 disposed under the semiconductor chips 4200, a connection structure 4400 for electrically connecting the semiconductor chips 4200 with the package substrate 4100, and a mold layer 4500 covering the semiconductor chips 4200 and the connection structure 4400 on the package substrate 4100.

The package substrate 4100 may be a printed circuit board (PCB) including package upper pads 4130. Each semiconductor chip 4200 may include an input/output pad 4210. The input/output pad 4210 may correspond to the input/output pad 3101 in FIG. 17. Each semiconductor chip 4200 may include gate electrode structures 4201, memory channel structures 4202 extending through the gate electrode structures 4201, and division structures 4203 for dividing the gate electrode structures 4201. Each semiconductor chip 4200 may include a nonvolatile memory device according to one or more embodiments described with reference to FIG. 1.

In one or more embodiments, the connection structure 4400 may be a bonding wire for electrically connecting the input/output pad 4210 and the package upper pads 4130.

FIG. 19 is a cross-sectional view of a nonvolatile memory device according to one or more embodiments.

Referring to FIG. 19, a memory device (or nonvolatile memory device) 5000 may have a chip-to-chip (C2C) structure. At least one upper chip including a cell region and a lower chip including a peripheral circuit region PREG may be manufactured separately, and then, the at least one upper chip and the lower chip may be connected to each other by a bonding method to realize the C2C structure. For example, the bonding method may mean a method of electrically or physically connecting a bonding metal pattern formed in an uppermost metal layer of the upper chip to a bonding metal pattern formed in an uppermost metal layer of the lower chip. For example, in a case in which the bonding metal patterns are formed of copper (Cu), the bonding method may be a Cu—Cu bonding method. Alternatively, the bonding metal patterns may be formed of aluminum (Al) or tungsten (W).

The memory device 5000 may include the at least one upper chip including the cell region. For example, as illustrated in FIG. 19, the memory device 5000 may include two upper chips. However, the number of the upper chips is not limited thereto. In the case in which the memory device 5000 includes the two upper chips, a first upper chip including a first cell region CREG1, a second upper chip including a second cell region CREG2 and the lower chip including the peripheral circuit region PREG may be manufactured separately, and then, the first upper chip, the second upper chip and the lower chip may be connected to each other by the bonding method to manufacture the memory device 5000. The first upper chip may be turned over and then may be connected to the lower chip by the bonding method, and the second upper chip may also be turned over and then may be connected to the first upper chip by the bonding method. Hereinafter, upper and lower portions of each of the first and second upper chips will be defined based on before each of the first and second upper chips is turned over. In other words, an upper portion of the lower chip may refer to an upper portion defined based on a +Z-axis direction, and the upper portion of each of the first and second upper chips may refer to an upper portion defined based on a −Z-axis direction in FIG. 19. However, embodiments are not limited thereto. In one or more embodiments, one of the first upper chip and the second upper chip may be turned over and then may be connected to a corresponding chip by the bonding method.

Each of the peripheral circuit region PREG and the first and second cell regions CREG1 and CREG2 of the memory device 5000 may include an external pad bonding region PA, a word line bonding region WLBA, and a bitline bonding region BLBA.

The peripheral circuit region PREG may include a first substrate 5210 and a plurality of circuit elements 5220a, 5220b and 5220c formed on the first substrate 5210. An interlayer insulating layer 5215 including one or more insulating layers may be provided on the plurality of circuit elements 5220a, 5220b and 5220c, and a plurality of metal lines electrically connected to the plurality of circuit elements 5220a, 5220b and 5220c may be provided in the interlayer insulating layer 5215. For example, the plurality of metal lines may include first metal lines 5230a, 5230b and 5230c connected to the plurality of circuit elements 5220a, 5220b and 5220c, and second metal lines 5240a, 5240b and 5240c formed on the first metal lines 5230a, 5230b and 5230c. The plurality of metal lines may be formed of at least one of various conductive materials. For example, the first metal lines 5230a, 5230b and 5230c may be formed of tungsten having a relatively high electrical resistivity, and the second metal lines 5240a, 5240b and 5240c may be formed of copper having a relatively low electrical resistivity.

The first metal lines 5230a, 5230b and 5230c and the second metal lines 5240a, 5240b and 5240c are illustrated and described in one or more embodiments. However, embodiments are not limited thereto. In one or more embodiments, at least one or more additional metal lines may further be formed on the second metal lines 5240a, 5240b and 5240c. In this case, the second metal lines 5240a, 5240b and 5240c may be formed of aluminum, and at least some of the additional metal lines formed on the second metal lines 5240a, 5240b and 5240c may be formed of copper having an electrical resistivity lower than that of aluminum of the second metal lines 5240a, 5240b and 5240c.

The interlayer insulating layer 5215 may be disposed on the first substrate 5210 and may include an insulating material such as silicon oxide and/or silicon nitride.

Each of the first and second cell regions CREG1 and CREG2 may include at least one memory block. The first cell region CREG1 may include a second substrate 5310 and a common source line 5320. A plurality of word lines 5330 (5331 to 5338) may be stacked on the second substrate 5310 in a direction (i.e., the Z-axis direction) perpendicular to a top surface of the second substrate 5310. String selection lines and a ground selection line may be disposed on and under the word lines 5330, and the plurality of word lines 5330 may be disposed between the string selection lines and the ground selection line. Likewise, the second cell region CREG2 may include a third substrate 5410 and a common source line 5420, and a plurality of word lines 5430 (5431 to 5438) may be stacked on the third substrate 5410 in a direction (i.e., the Z-axis direction) perpendicular to a top surface of the third substrate 5410. Each of the second substrate 5310 and the third substrate 5410 may be formed of at least one of various materials and may be, for example, a silicon substrate, a silicon-germanium substrate, a germanium substrate, or a substrate having a single-crystalline epitaxial layer grown on a single-crystalline silicon substrate. A plurality of channel structures CH may be formed in each of the first and second cell regions CREG1 and CREG2.

In one or more embodiments, as illustrated in a region ‘A1’, the channel structure CH may be provided in the bitline bonding region BLBA and may extend in the direction perpendicular to the top surface of the second substrate 5310 to penetrate the word lines 5330, the string selection lines, and the ground selection line. The channel structure CH may include a data storage layer, a channel layer, and a filling insulation layer. The channel layer may be electrically connected to a first metal line 5350c and a second metal line 5360c in the bitline bonding region BLBA. For example, the second metal line 5360c may be a bitline and may be connected to the channel structure CH through the first metal line 5350c. The metal line 5360c may extend in a first direction (e.g., a Y-axis direction) parallel to the top surface of the second substrate 5310.

In one or more embodiments, as illustrated in a region ‘A2’, the channel structure CH may include a lower channel LCH and an upper channel UCH, which are connected to each other. For example, the channel structure CH may be formed by a process of forming the lower channel LCH and a process of forming the upper channel UCH. The lower channel LCH may extend in the direction perpendicular to the top surface of the second substrate 5310 to penetrate the common source line 5320 and lower word lines 5331 and 5332. The lower channel LCH may include a data storage layer, a channel layer, and a filling insulation layer and may be connected to the upper channel UCH. The upper channel UCH may penetrate upper word lines 5333 to 5338. The upper channel UCH may include a data storage layer, a channel layer, and a filling insulation layer, and the channel layer of the upper channel UCH may be electrically connected to the first metal line 5350c and the second metal line 5360c. As a length of a channel increases, due to characteristics of manufacturing processes, it may be difficult to form a channel having a substantially uniform width. The memory device 5000 according to one or more embodiments may include a channel having improved width uniformity due to the lower channel LCH and the upper channel UCH which are formed by the processes performed sequentially.

In the case in which the channel structure CH includes the lower channel LCH and the upper channel UCH as illustrated in the region ‘A2’, a word line located near to a boundary between the lower channel LCH and the upper channel UCH may be a dummy word line. For example, the word lines 5332 and 5333 adjacent to the boundary between the lower channel LCH and the upper channel UCH may be the dummy word lines. In this case, data may not be stored in memory cells connected to the dummy word line. Alternatively, the number of pages corresponding to the memory cells connected to the dummy word line may be less than the number of pages corresponding to the memory cells connected to a general word line. A level of a voltage applied to the dummy word line may be different from a level of a voltage applied to the general word line, and thus an influence of a non-uniform channel width between the lower and upper channels LCH and UCH on an operation of the memory device may be reduced.

In one or more embodiments, the number of the lower word lines 5331 and 5332 penetrated by the lower channel LCH is less than the number of the upper word lines 5333 to 5338 penetrated by the upper channel UCH in the region ‘A2’. However, embodiments are not limited thereto. In one or more embodiments, the number of the lower word lines penetrated by the lower channel LCH may be equal to or more than the number of the upper word lines penetrated by the upper channel UCH. In addition, structural features and connection relation of the channel structure CH disposed in the second cell region CREG2 may be substantially the same as those of the channel structure CH disposed in the first cell region CREG1.

In the bitline bonding region BLBA, a first through-electrode THV1 may be provided in the first cell region CREG1, and a second through-electrode THV2 may be provided in the second cell region CREG2. As illustrated in FIG. 19, the first through-electrode THV1 may penetrate the common source line 5320 and the plurality of word lines 5330. In one or more embodiments, the first through-electrode THV1 may further penetrate the second substrate 5310. The first through-electrode THV1 may include a conductive material. Alternatively, the first through-electrode THV1 may include a conductive material surrounded by an insulating material. The second through-electrode THV2 may have the same shape and structure as the first through-electrode THV1.

In one or more embodiments, the first through-electrode THV1 and the second through-electrode THV2 may be electrically connected to each other through a first through-metal pattern 5372d and a second through-metal pattern 5472d. The first through-metal pattern 5372d may be formed at a bottom end of the first upper chip including the first cell region CREG1, and the second through-metal pattern 5472d may be formed at a top end of the second upper chip including the second cell region CREG2. The first through-electrode THV1 may be electrically connected to the first metal line 5350c and the second metal line 5360c. A lower via 5371d may be formed between the first through-electrode THV1 and the first through-metal pattern 5372d, and an upper via 5471d may be formed between the second through-electrode THV2 and the second through-metal pattern 5472d. The first through-metal pattern 5372d and the second through-metal pattern 5472d may be connected to each other by the bonding method.

In addition, in the bitline bonding region BLBA, an upper metal pattern 5252 may be formed in an uppermost metal layer of the peripheral circuit region PERI, and an upper metal pattern 5392 having the same shape as the upper metal pattern 5252 may be formed in an uppermost metal layer of the first cell region CREG1. The upper metal pattern 5392 of the first cell region CREG1 and the upper metal pattern 5252 of the peripheral circuit region PREG may be electrically connected to each other by the bonding method. In the bitline bonding region BLBA, the metal line 5360c may be electrically connected to a page buffer included in the peripheral circuit region PERI. For example, some of the circuit elements 5220c of the peripheral circuit region PREG may constitute the page buffer, and the metal line 5360c may be electrically connected to the circuit elements 5220c constituting the page buffer through an upper bonding metal pattern 5370c of the first cell region CREG1 and an upper bonding metal pattern 5270c of the peripheral circuit region PERI.

In the word line bonding region WLBA, the word lines 5330 of the first cell region CREG1 may extend in a second direction (e.g., an X-axis direction) parallel to the top surface of the second substrate 5310 and may be connected to a plurality of cell contact plugs 5340 (5341 to 5347). First metal lines 5350b and second metal lines 5360b may be sequentially connected onto the cell contact plugs 5340 connected to the word lines 5330. In the word line bonding region WLBA, the cell contact plugs 5340 may be connected to the peripheral circuit region PREG through upper bonding metal patterns 5370b of the first cell region CREG1 and upper bonding metal patterns 5270b of the peripheral circuit region PERI.

The cell contact plugs 5340 may be electrically connected to a row decoder included in the peripheral circuit region PERI. For example, some of the circuit elements 5220b of the peripheral circuit region PREG may constitute the row decoder, and the cell contact plugs 5340 may be electrically connected to the circuit elements 5220b constituting the row decoder through the upper bonding metal patterns 5370b of the first cell region CREG1 and the upper bonding metal patterns 5270b of the peripheral circuit region PERI. In one or more embodiments, an operating voltage of the circuit elements 5220b constituting the row decoder may be different from an operating voltage of the circuit elements 5220c constituting the page buffer. For example, the operating voltage of the circuit elements 5220c constituting the page buffer may be greater than the operating voltage of the circuit elements 5220b constituting the row decoder.

Likewise, in the word line bonding region WLBA, the word lines 5430 of the second cell region CREG2 may extend in the second direction (e.g., the X-axis direction) parallel to the top surface of the third substrate 5410 and may be connected to a plurality of cell contact plugs 5440 (5441 to 5447). The cell contact plugs 5440 may be connected to the peripheral circuit region PREG through an upper metal pattern of the second cell region CREG2 and lower and upper metal patterns and a cell contact plug 5348 of the first cell region CREG1.

In the word line bonding region WLBA, the upper bonding metal patterns 5370b may be formed in the first cell region CREG1, and the upper bonding metal patterns 5270b may be formed in the peripheral circuit region PERI. The upper bonding metal patterns 5370b of the first cell region CREG1 and the upper bonding metal patterns 5270b of the peripheral circuit region PREG may be electrically connected to each other by the bonding method. The upper bonding metal patterns 5370b and the upper bonding metal patterns 5270b may be formed of aluminum, copper, or tungsten.

In the external pad bonding region PA, a lower metal pattern 5371e may be formed in a lower portion of the first cell region CREG1, and an upper metal pattern 5472a may be formed in an upper portion of the second cell region CREG2. The lower metal pattern 5371e of the first cell region CREG1 and the upper metal pattern 5472a of the second cell region CREG2 may be connected to each other by the bonding method in the external pad bonding region PA. Likewise, an upper metal pattern 5372a may be formed in an upper portion of the first cell region CREG1, and an upper metal pattern 5272a may be formed in an upper portion of the peripheral circuit region PERI. The upper metal pattern 5372a of the first cell region CREG1 and the upper metal pattern 5272a of the peripheral circuit region PREG may be connected to each other by the bonding method.

Common source line contact plugs 5380 and 5480 may be disposed in the external pad bonding region PA. The common source line contact plugs 5380 and 5480 may be formed of a conductive material such as a metal, a metal compound, and/or doped polysilicon. The common source line contact plug 5380 of the first cell region CREG1 may be electrically connected to the common source line 5320, and the common source line contact plug 5480 of the second cell region CREG2 may be electrically connected to the common source line 5420. A first metal line 5350a and a second metal line 5360a may be sequentially stacked on the common source line contact plug 5380 of the first cell region CREG1, and a first metal line 5450a and a second metal line 5460a may be sequentially stacked on the common source line contact plug 5480 of the second cell region CREG2.

Input/output pads 5205, 5405 and 5406 may be disposed in the external pad bonding region PA. A lower insulating layer 5201 may cover a bottom surface of the first substrate 5210, and a first input/output pad 5205 may be formed on the lower insulating layer 5201. The first input/output pad 5205 may be connected to at least one of a plurality of the circuit elements 5220a disposed in the peripheral circuit region PREG through a first input/output contact plug 5203 and may be separated from the first substrate 5210 by the lower insulating layer 5201. In addition, a side insulating layer may be disposed between the first input/output contact plug 5203 and the first substrate 5210 to electrically isolate the first input/output contact plug 5203 from the first substrate 5210.

An upper insulating layer 5401 covering atop surface of the third substrate 5410 may be formed on the third substrate 5410. A second input/output pad 5405 and/or a third input/output pad 5406 may be disposed on the upper insulating layer 5401. The second input/output pad 5405 may be connected to at least one of the plurality of circuit elements 5220a disposed in the peripheral circuit region PREG through second input/output contact plugs 5403 and 5303, and the third input/output pad 5406 may be connected to at least one of the plurality of circuit elements 5220a disposed in the peripheral circuit region PREG through third input/output contact plugs 5404 and 5304.

In one or more embodiments, the third substrate 5410 may not be disposed in a region in which the input/output contact plug is disposed. For example, as illustrated in a region ‘B’, the third input/output contact plug 5404 may be separated from the third substrate 5410 in a direction parallel to the top surface of the third substrate 5410 and may penetrate an interlayer insulating layer 5415 of the second cell region CREG2 so as to be connected to the third input/output pad 5406. In this case, the third input/output contact plug 5404 may be formed by at least one of various processes.

In one or more embodiments, as illustrated in a region ‘B1’, the third input/output contact plug 5404 may extend in a third direction (e.g., the Z-axis direction), and a diameter of the third input/output contact plug 5404 may become progressively greater toward the upper insulating layer 5401. In other words, a diameter of the channel structure CH described in the region ‘A1’ may become progressively less toward the upper insulating layer 5401, but the diameter of the third input/output contact plug 5404 may become progressively greater toward the upper insulating layer 5401. For example, the third input/output contact plug 5404 may be formed after the second cell region CREG2 and the first cell region CREG1 are bonded to each other by the bonding method.

In one or more embodiments, as illustrated in a region ‘B2’, the third input/output contact plug 5404 may extend in the third direction (e.g., the Z-axis direction), and a diameter of the third input/output contact plug 5404 may become progressively less toward the upper insulating layer 5401. In other words, like the channel structure CH, the diameter of the third input/output contact plug 5404 may become progressively less toward the upper insulating layer 5401. For example, the third input/output contact plug 5404 may be formed together with the cell contact plugs 5440 before the second cell region CREG2 and the first cell region CREG1 are bonded to each other.

In one or more embodiments, the input/output contact plug may overlap with the third substrate 5410. For example, as illustrated in a region ‘C’, the second input/output contact plug 5403 may penetrate the interlayer insulating layer 5415 of the second cell region CREG2 in the third direction (e.g., the Z-axis direction) and may be electrically connected to the second input/output pad 5405 through the third substrate 5410. In this case, a connection structure of the second input/output contact plug 5403 and the second input/output pad 5405 may be realized by various methods.

In one or more embodiments, as illustrated in a region ‘C1’, an opening 5408 may be formed to penetrate the third substrate 5410, and the second input/output contact plug 5403 may be connected directly to the second input/output pad 5405 through the opening 5408 formed in the third substrate 5410. In this case, as illustrated in the region ‘C1’, a diameter of the second input/output contact plug 5403 may become progressively greater toward the second input/output pad 5405. However, embodiments are not limited thereto, and in one or more embodiments, the diameter of the second input/output contact plug 5403 may become progressively less toward the second input/output pad 5405.

In one or more embodiments, as illustrated in a region ‘C2’, the opening 5408 penetrating the third substrate 5410 may be formed, and a contact 5407 may be formed in the opening 5408. An end of the contact 5407 may be connected to the second input/output pad 5405, and another end of the contact 5407 may be connected to the second input/output contact plug 5403. Thus, the second input/output contact plug 5403 may be electrically connected to the second input/output pad 5405 through the contact 5407 in the opening 5408. In this case, as illustrated in the region ‘C2’, a diameter of the contact 5407 may become progressively greater toward the second input/output pad 5405, and a diameter of the second input/output contact plug 5403 may become progressively less toward the second input/output pad 5405. For example, the second input/output contact plug 5403 may be formed together with the cell contact plugs 5440 before the second cell region CREG2 and the first cell region CREG1 are bonded to each other, and the contact 5407 may be formed after the second cell region CREG2 and the first cell region CREG1 are bonded to each other.

In one or more embodiments illustrated in a region ‘C3’, a stopper 5409 may further be formed on a bottom end of the opening 5408 of the third substrate 5410, as compared with the embodiments of the region ‘C2’. The stopper 5409 may be a metal line formed in the same layer as the common source line 5420. Alternatively, the stopper 5409 may be a metal line formed in the same layer as at least one of the word lines 5430. The second input/output contact plug 5403 may be electrically connected to the second input/output pad 5405 through the contact 5407 and the stopper 5409.

Like the second and third input/output contact plugs 5403 and 5404 of the second cell region CREG2, a diameter of each of the second and third input/output contact plugs 5303 and 5304 of the first cell region CREG1 may become progressively less toward the lower metal pattern 5371e or may become progressively greater toward the lower metal pattern 5371e.

In one or more embodiments, a slit 5411 may be formed in the third substrate 5410. For example, the slit 5411 may be formed at a certain position of the external pad bonding region PA. For example, as illustrated in a region ‘E, the slit 5411 may be located between the second input/output pad 5405 and the cell contact plugs 5440 when viewed in a plan view. Alternatively, the second input/output pad 5405 may be located between the slit 5411 and the cell contact plugs 5440 when viewed in a plan view.

In one or more embodiments, as illustrated in a region ‘E1’, the slit 5411 may be formed to penetrate the third substrate 5410. For example, the slit 5411 may be used to prevent the third substrate 5410 from being finely cracked when the opening 5408 is formed. However, embodiments are not limited thereto, and in one or more embodiments, the slit 5411 may be formed to have a depth ranging from about 60% to about 70% of a thickness of the third substrate 5410.

In one or more embodiments, as illustrated in a region ‘E2’, a conductive material 5412 may be formed in the slit 5411. For example, the conductive material 5412 may be used to discharge a leakage current occurring in driving of the circuit elements in the external pad bonding region PA to the outside. In this case, the conductive material 5412 may be connected to an external ground line.

In one or more embodiments, as illustrated in a region ‘E3’, an insulating material 5413 may be formed in the slit 5411. For example, the insulating material 5413 may be used to electrically isolate the second input/output pad 5405 and the second input/output contact plug 5403 disposed in the external pad bonding region PA from the word line bonding region WLBA. Since the insulating material 5413 is formed in the slit 5411, it is possible to prevent a voltage provided through the second input/output pad 5405 from affecting a metal layer disposed on the third substrate 5410 in the word line bonding region WLBA.

In one or more embodiments, the first to third input/output pads 5205, 5405 and 5406 may be selectively formed. For example, the memory device 5000 may be realized to include only the first input/output pad 5205 disposed on the first substrate 5210, to include only the second input/output pad 5405 disposed on the third substrate 5410, or to include only the third input/output pad 5406 disposed on the upper insulating layer 5401.

In one or more embodiments, at least one of the second substrate 5310 of the first cell region CREG1 or the third substrate 5410 of the second cell region CREG2 may be used as a sacrificial substrate and may be completely or partially removed before or after a bonding process. An additional layer may be stacked after the removal of the substrate. For example, the second substrate 5310 of the first cell region CREG1 may be removed before or after the bonding process of the peripheral circuit region PREG and the first cell region CREG1, and then, an insulating layer covering a top surface of the common source line 5320 or a conductive layer for connection may be formed. Likewise, the third substrate 5410 of the second cell region CREG2 may be removed before or after the bonding process of the first cell region CREG1 and the second cell region CREG2, and then, the upper insulating layer 5401 covering a top surface of the common source line 5420 or a conductive layer for connection may be formed.

Example embodiments may be applied to various electronic devices and systems that include a nonvolatile memory device. For example, the inventive concept may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, etc.

In the nonvolatile memory device and the memory package according to one or more embodiments, a plurality of string selection line ground transistors may be spaced apart from a plurality of string selection line pass transistors. The plurality of string selection line ground transistors may be disposed in a cell array area, and the chip size may be reduced as a non-buried area (e.g., an X decoder area) is reduced. As the plurality of string selection line ground transistors may be disposed adjacent to the center of a string selection line, data loading speed may be increased, and driving performance may be improved.

At least one of the devices, units, components, modules, units, or the like represented by a block or an equivalent indication in the above embodiments including, but not limited to, FIGS. 11, 14 and 17, may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

Each of the embodiments provided in the above description is not excluded from being associated with one or more features of another example or another embodiment also provided herein or not provided herein but consistent with the disclosure

While the disclosure has been particularly shown and described with reference to embodiments thereof, it will be understood that various changes in form and details may be made therein without departing from the spirit and scope of the following claims.

What is claimed is:

1. A nonvolatile memory device comprising:
a first semiconductor layer comprising:
a first substrate;
a memory cell array on the first substrate and in a cell array area; and
a plurality of word lines and a string selection line extending in a first direction parallel to an upper surface of the first substrate and provided along a second direction intersecting the first direction, the plurality of word lines and the string selection line being connected to the memory cell array; and
a second semiconductor layer comprising:
a second substrate; and
a peripheral circuit on the second substrate and configured to control the memory cell array, the peripheral circuit comprising:
a plurality of word line pass transistors, each word line pass transistor of the plurality of word line pass transistors connected to one word line of the plurality of word lines;
a plurality of string selection line pass transistors connected to the string selection line; and
a plurality of string selection line ground transistors in the cell array area and spaced apart from the plurality of string selection line pass transistors, the plurality of string selection line ground transistors configured to provide a ground voltage to the string selection line.

2. The nonvolatile memory device of claim 1, wherein the plurality of word line pass transistors and the plurality of string selection line pass transistors are in a decoder area adjacent to the cell array area in the first direction.

3. The nonvolatile memory device of claim 2, wherein, in a cross-sectional view, the plurality of word lines and the string selection line are provided in a step-shaped multi-layer structure.

4. The nonvolatile memory device of claim 3, wherein the step-shaped multi-layer structure is in the decoder area.

5. The nonvolatile memory device of claim 1, wherein the memory cell array comprises:
a first memory cell array and a second memory cell array adjacent to the first memory cell array, and
wherein the first memory cell array and the second memory cell array share the plurality of word lines and the string selection line.

6. The nonvolatile memory device of claim 5, wherein the plurality of word line pass transistors comprise first word line pass transistors and second word line pass transistors,
wherein the plurality of string selection line pass transistors comprise first string selection line pass transistors and second string selection line pass transistors,
wherein the first word line pass transistors and the first string selection line pass transistors are connected to the first memory cell array and are adjacent to a first side of the cell array area, and
wherein the second word line pass transistors and the second string selection line pass transistors are connected to the second memory cell array and adjacent to a second side of the cell array area that is opposite to the first side of the cell array area.

7. The nonvolatile memory device of claim 5, wherein the plurality of string selection line ground transistors are adjacent to a boundary between the first memory cell array and the second memory cell array.

8. The nonvolatile memory device of claim 1, wherein the second semiconductor layer further comprises a first well, a second well, and a third well in the second substrate, and
wherein the plurality of word line pass transistors are in the first well, the plurality of string selection line pass transistors are in the second well, and the plurality of string selection line ground transistors are in the third well.

9. The nonvolatile memory device of claim 8, wherein the third well is in the cell array area, and
wherein the first well and the second well are in a decoder area adjacent to the cell array area in the first direction.

10. The nonvolatile memory device of claim 9, wherein the second well and the third well are spaced apart from each other in the first direction.

11. The nonvolatile memory device of claim 1, wherein the first semiconductor layer further comprises a ground selection line extending in the first direction and connected to the memory cell array, and
wherein the second semiconductor layer further comprises a plurality of ground selection line pass transistors connected to the ground selection line.

12. The nonvolatile memory device of claim 11, wherein the second semiconductor layer further comprises a first well, a second well, a third well, and a fourth well in the second substrate, and
wherein the plurality of word line pass transistors are in the first well, the plurality of string selection line pass transistors are in the second well, the plurality of string selection line ground transistors are in the third well, and the plurality of ground selection line pass transistors are in the fourth well.

13. The nonvolatile memory device of claim 12, wherein the first well is in a decoder area adjacent to the cell array area in the first direction,
wherein the third well is in the cell array area, and
wherein at least one of the second well and the fourth well is in the cell array area.

14. The nonvolatile memory device of claim 1, wherein at least one string selection line pass transistor of the plurality of string selection line pass transistors is in the cell array area and configured as a gate induced drain leakage (GIDL) pass transistor that operates based on a GIDL phenomenon.

15. The nonvolatile memory device of claim 1, wherein the first semiconductor layer further comprises:
a plurality of first bonding pads, each first bonding pad of the plurality of first bonding pads being connected to one word line of the plurality of word lines by a respective first vertical wire of a plurality of first vertical wires; and
a plurality of second bonding pads respectively connected to the string selection line by a plurality of second vertical wires, and
wherein the second semiconductor layer further comprises:
a plurality of third bonding pads, wherein each third bonding pad of the plurality of third bonding pads is connected to one word line pass transistor of the plurality of word line pass transistors by a respective third vertical wire of a plurality of third vertical wires, and wherein the plurality of third bonding pads are respectively connected to the plurality of first bonding pads; and
a plurality of fourth bonding pads respectively connected to the plurality of string selection line pass transistors by a plurality of fourth vertical wires.

16. The nonvolatile memory device of claim 15, wherein a first bonding pad of the plurality of second bonding pads connected to the string selection line and a first bonding pad of the plurality of fourth bonding pads connected to at least one string selection line ground transistor of the plurality of string selection line ground transistors are in the cell array area.

17. The nonvolatile memory device of claim 15, wherein a first bonding pad of the plurality of second bonding pads connected to the string selection line and a first bonding pad of the plurality of fourth bonding pads connected to at least one string selection line ground transistor of the plurality of string selection line ground transistors are in a decoder area adjacent to the cell array area in the first direction.

18. The nonvolatile memory device of claim 1, wherein the second semiconductor layer further comprises:
a word line driver connected to the plurality of word line pass transistors and configured to supply word line voltages to the plurality of word lines; and
a string selection line driver connected to the plurality of string selection line ground transistors and the plurality of string selection line pass transistors, the string selection line driver configured to supply an string selection line voltage and the ground voltage to the string selection line, and
wherein the word line driver and the string selection line driver are in a decoder area adjacent to the cell array area in the first direction.

19. A memory package comprising:
a base substrate; and
a plurality of memory chips on the base substrate,
wherein each memory chip of the plurality of memory chips comprises:
a first semiconductor layer comprising:
a first substrate;
a memory cell array on the first substrate and in a cell array area; and
a plurality of word lines and a string selection line extending in a first direction parallel to an upper surface of the first substrate and provided along a second direction intersecting the first direction, the plurality of word lines and the string selection line being connected to the memory cell array,
a second semiconductor layer comprising:
a second substrate; and
a peripheral circuit on the second substrate and configured to control the memory cell array, the peripheral circuit comprising;
a plurality of word line pass transistors, each word line pass transistor of the plurality of word line pass transistors connected to one word line of the plurality of word lines;
a plurality of string selection line pass transistors connected to the string selection line; and
a plurality of string selection line ground transistors in the cell array area and spaced apart from the plurality of string selection line pass transistors, the plurality of string selection line ground transistors configured to provide a ground voltage to the string selection line.

20. A nonvolatile memory device comprising:
a first semiconductor layer comprising:
a first substrate;
a memory cell array on the first substrate and in a cell array area, the memory cell array comprising a first memory cell array and a second memory cell array adjacent to the first memory cell array; and
a plurality of word lines and a string selection line extending in a first direction parallel to an upper surface of the first substrate and provided along a second direction intersecting the first direction, the plurality of word lines and the string selection line being connected to the memory cell array, and
a second semiconductor layer comprising:
a second substrate;
a peripheral circuit on the second substrate and configured to control the memory cell array; and
a first well, a second well, and a third well;
wherein the peripheral circuit comprises:
a plurality of word line pass transistors in the first well, each word line pass transistor of the plurality of word line pass transistors connected to one word line of the plurality of word lines;
a plurality of string selection line pass transistors in the second well and connected to the string selection line; and
a plurality of string selection line ground transistors in the third well, in the cell array area, and spaced apart from the plurality of string selection line pass transistors, the plurality of string selection line ground transistors configured to provide a ground voltage to the string selection line,
wherein the first memory cell array and the second memory cell array share the plurality of word lines and the string selection line,
wherein the third well is in the cell array area, and
wherein the first well and the second well are in a decoder area adjacent to the cell array area in the first direction.
